(19) United States
(12) Patent Application Publication
(10) Pub. No.: US 2013/0234724 A1
(43) Pub. Date: Sep. 12, 2013

(54) DISCRIMINATING APPARATUS, DISCRIMINATING METHOD AND DISCRIMINATING SYSTEM

(71) Applicants: SONY CORPORATION, Tokyo (JP); SONY COMPUTER ENTERTAINMENT INC., Tokyo (JP)

(72) Inventors: HIDETOSHI KABASAWA, Tokyo (JP); TAKAYUKI HIRABAYASHI, Tokyo (JP); HIDEO NIIKURA, Tokyo (JP); MASAKAZU YAJIMA, Tokyo (JP); KOHEI SHIMIZU, Tokyo (JP); SHINICHI HONDA, Tokyo (JP)

(73) Assignees: SONY COMPUTER ENTERTAINMENT INC., Tokyo (JP); SONY CORPORATION, Tokyo (JP)

(21) Appl. No.: 13/785,977

(22) Filed: Mar. 5, 2013

(30) Foreign Application Priority Data
Mar. 8, 2012 (JP) 2012-051556

(51) Int. Cl. G01R 31/00

(52) U.S. Cl. CPC G01R 31/00
USPC 324/537

(57) ABSTRACT

A discriminating apparatus includes a discrimination section configured to discriminate the presence or absence of an abnormality, in accordance with information on power generation from a power generation section.

### BACKGROUND

The present disclosure relates to a discriminating apparatus, which determines the presence or absence of an abnormality for example, and also relates to a discriminating method and a discriminating system.

By using sensors, detections of behaviors of target have been made (see, for example, Japanese Patent Application Laid-open No. 2006-340903). As a power source for driving the sensor, batteries are commonly used.

### SUMMARY

In order to detect the behavior of the target, the sensor may need to be driven constantly. Therefore, it was necessary to replace the battery and charge the battery, and thus there has been the problem of being cumbersome. Further, there has been the problem that in the cases where a battery replacement or charging of the battery was neglected, the sensor's operation might stop and the necessary data would not be acquired. In addition, in the cases where a commercial power supply is used as a power source, there have been the problems that electricity prices would be charged, it would be costly to lay the commercial power supply, and a freedom of layout would be restricted.

In view of the circumstances as described above, it is thus desirable to provide a discriminating apparatus, a discriminating method and a discriminating system, capable of discriminating the presence or absence of an abnormality even when there are no batteries used or when the power supply from the battery is stopped.

According to the present disclosure, for example, there is provided a discriminating apparatus including a discrimination section configured to discriminate the presence or absence of an abnormality, in accordance with information on power generation from a power generation section.

According to the present disclosure, for example, there is further provided a discriminating method in a discriminating apparatus, including, discriminating the presence or absence of an abnormality in accordance with information on power generation from a power generation section.

According to the present disclosure, for example, there is still further provided a discriminating system, including, a power generation section which generates power on the basis of the energy present in the surrounding environment; and a discrimination section configured to discriminate the presence or absence of an abnormality, in accordance with information on power generation from the power generation section.

According to at least one of the embodiments of the present disclosure, even when there are no batteries used, or even when the power supply from the battery is stopped, the presence or absence of an abnormality is able to be determined.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing an example of partition of a power-generating floor;

FIG. 2 is a diagram showing an example of a cross-section of a power-generating floor;

FIG. 3 is a diagram for illustrating an example of arrangement of electrodes;

FIG. 4 is a diagram for illustrating an example of a position of power generation element which generates power;

FIG. 5 is a diagram for illustrating another example of positions of power generation elements which generate power;

FIG. 6 is a diagram for illustrating an example of patterns of flow lines;

FIG. 7 is a diagram showing an example of a configuration of a discriminating apparatus and an external apparatus;

FIG. 8 is a flowchart for illustrating an example of process by a discriminating apparatus;

FIGS. 9A to 9D are diagrams showing an example of the change in speed, and the like, when a user is moving;

FIGS. 10A to 10D are diagrams showing an example of the change in speed, and the like, when a suspicious individual is moving;

FIG. 11 is a diagram for illustrating an overview of a mobile terminal;

FIG. 12 is a diagram showing an example of a configuration of a mobile terminal and an external apparatus;

FIG. 13 is a flowchart for illustrating an example of process by a mobile terminal;

FIG. 14 is a flowchart for illustrating another example of process by a mobile terminal;

FIGS. 15A to 15D are diagrams showing an example of the change in speed, and the like, of a vehicle;

FIG. 16 is a diagram showing an example of a configuration of a vehicle apparatus and an external apparatus; and

FIG. 17 is a flowchart for illustrating an example of process by a vehicle apparatus.

### DETAILED DESCRIPTION OF EMBODIMENT

Hereinafter, embodiments of the present disclosure will be described with reference to the drawings.

The embodiments of the present disclosure will be described in the following order.

<1. First embodiment>
<2. Second embodiment>
<3. Third embodiment>
<4. Modified examples>

It should be noted that the following embodiments and modified examples are preferred concrete examples of the present disclosure, and the content of the present disclosure is not limited to these embodiments and modified examples.

A power generation section in the present disclosure generates power on the basis of the energy present in the surrounding environment. The power generation section may generate power on the basis of light and heat, vibrations, and radio waves, for example. These energies are not limited to those that exist in nature. For example, the heat emitted by a moving object such as users and vehicles (for example, heat of the surface of the user's body, or heat emitted by the engine of the vehicle), pressures and vibrations caused by the movement of the moving object, and electromagnetic waves emitted by electronic apparatus that the user or the moving object holds, may be included in the energies.

### 1. First Embodiment

First, a first embodiment will be described. In the first embodiment, an intrusion of a suspicious individual into a predetermined space will be described as an example of an abnormality. In the first embodiment, a power-generating floor is used. The power-generating floor is, for example, one which has a plurality of power generation elements built into a contact member, such as flooring materials and carpets, to be brought into contact with a user. Needless to say, the contact member is not limited to such as flooring materials. In addition, this is not limited to ones provided in such a manner to be brought into contact with the sole of the foot and the shoe soles. For example, wheels of vehicles may come into contact with the power-generating floor. Furthermore, ways of coming into contact with the contact member are not limited to direct contacts, and may include indirect contacts such as one in which a user is walking over a carpet laid on the power-generating floor.

“Overview of Power-Generating Floor”

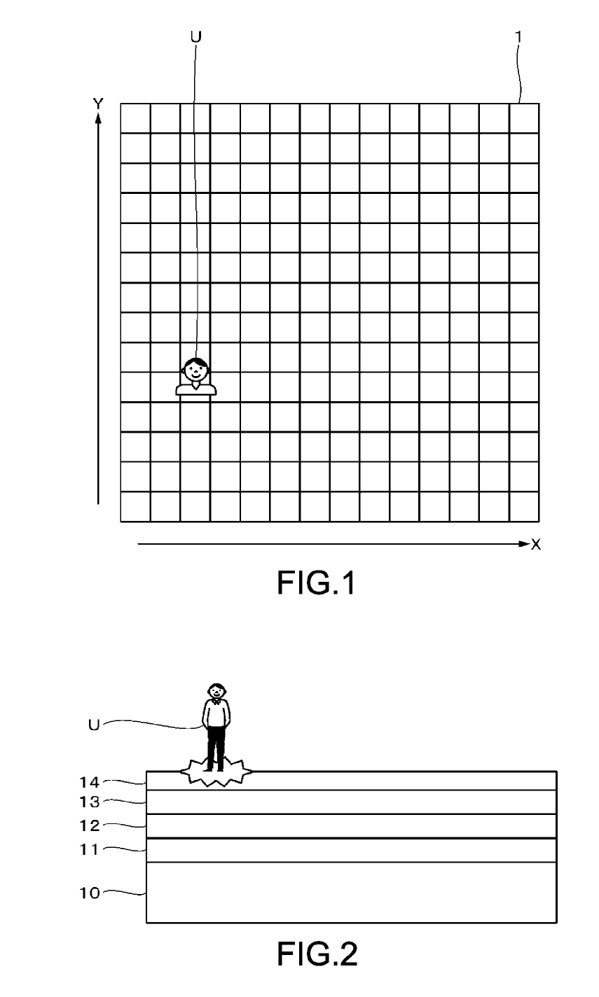

FIG. 1 is an example of a diagram (top view) of the power-generating floor viewed from the top. A power-generating floor 1 is, for example, divided into a plurality of blocks BL, each of which blocks BL having its position defined by X and Y coordinates. On the power-generating floor 1, a user U, as an example of the moving object, would be moving. The power generation element is built into the corresponding position at each block BL. In addition, usually, partitions of the blocks BL is not to be displayed on the surface of the power-generating floor 1, and therefore, the partitioned area that the user U is moving is not able to be recognized by this user U.

The power generation element is, for example, a piezoelectric element having a configuration with a piezoelectric material and with electrodes on the both ends of the piezoelectric material. Since the mechanism in piezoelectric elements of generating voltage has been already known, the description will be given only in brief outline. When a pressure is given to a piezoelectric material to be generating a strain, electrical charges due to the polarization phenomenon appear on the surfaces and are observed as a voltage. Conversely, when a tension is given to the piezoelectric material, a voltage of opposite sign is to be observed.

Examples of piezoelectric materials are lead zirconate titanate (PZT), lead titanate (PbTiO₃), lithium tantalite (LiTaO₃), lithium niobate (LiNbO₃), lithium tetraborate (Li₂B₄O₇), langasite (La₃Ga₅SiO₁₄), quartz (SiO₂), zinc oxide (ZnO), potassium sodium tartrate (KNaC₄H₄O₆), aluminum nitride (AlN), tourmaline (silicate mineral), polyvinylidene difluoride (PVDF), VDF (vinylidene fluoride) oligomer, fluorine-based piezoelectric materials and the like. These materials may include those in bulk form, those obtained by thin film deposition, and those which are coated.

By a pressure which occurs when being stepped on by the user U at the time of movement, the power generation element of the block BL where the user U has moved generates power. For example, in FIG. 1, the power generation element of the position at coordinates (3, 5) generates power. Accordingly, it can be discriminated that the user is moving on the block BL of the coordinates (3, 5). In the case where the history of the positions of the power generation elements having generated power is taken, it is possible to obtain the trajectory of the movement of the user U.

FIG. 2 is a cross-sectional view showing an example of a cross-section of a power-generating floor. On a base layer 10 such as one of substrates, films and sheets, there are laminated a lower electrode 11, a piezoelectric material (piezoelectric film or piezoelectric sheet) 12 and an upper electrode 13. A surface of the upper electrode 13 is coated with a protective film 14. The user U moves over the protective film 14. At a place where the user U has moved, the generation of power occurs. Examples of methods for laminating these parts include vapor deposition, sputtering, coating, casting, laminating, printing and the like. Among these methods, taking into account the material of the base layer 10 and the type of the piezoelectric material 12, an appropriate method may be selected. It should be noted that in FIG. 2, supporting members for supporting each of the lower electrode 11 and the upper electrode 13 are not shown. In the cases where the lower electrode 11 and the upper electrode 13 are directly laminated (by vapor deposition, sputtering, coating or the like) on the piezoelectric element, the supporting members would be unnecessary.

“Example of Arrangement of Electrodes”

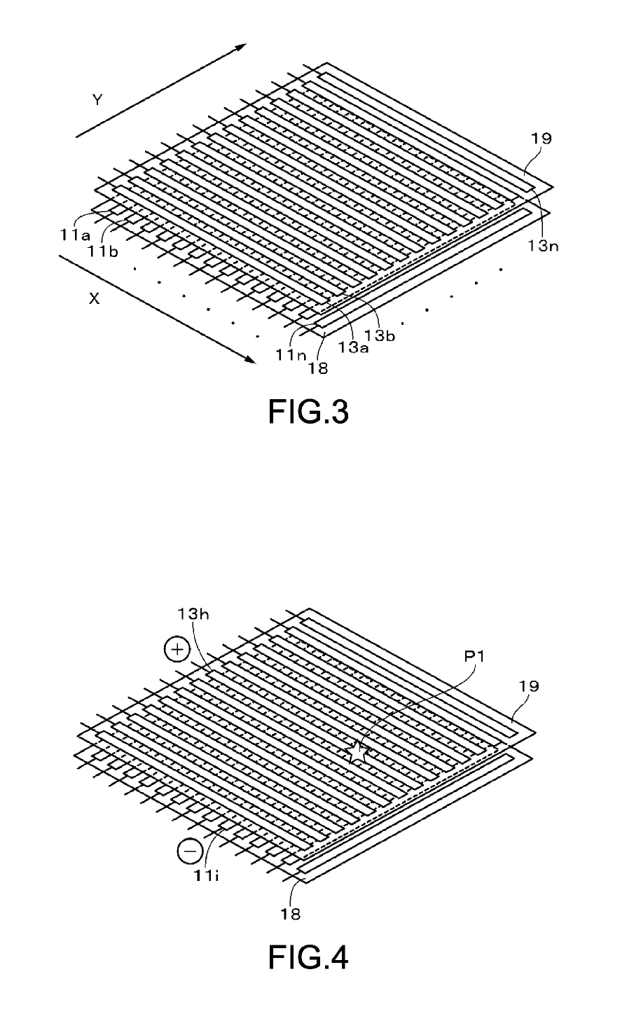

FIG. 3 shows an example of arrangement of the lower electrode 11 and the upper electrode 13. The lower electrode 11 includes, for example, a plurality of strip-shaped electrodes. The configuration of the lower electrode 11 is one in which the plurality of strip-shaped electrodes (an electrode 11a, an electrode 11b, an electrode 11c . . . an electrode 11n) is stuck on one surface of a sheet 18. Herein, unless a distinction of the individual electrodes is necessary, these electrodes will simply be referred to as the lower electrode 11.

The upper electrode 13 includes, for example, a plurality of strip-shaped electrodes. The configuration of the upper electrode 13 is one in which the plurality of strip-shaped electrodes (an electrode 13a, an electrode 13b, an electrode 13c . . . an electrode 13n) is stuck on one surface of a sheet 19. Herein, unless a distinction of the individual electrodes is necessary, these electrodes will simply be referred to as the upper electrode 13. In addition, size and shape of the sheets, the number, size, shape and the like of the electrodes may be set appropriately depending on factors such as size of the power-generating floor 1.

The lower electrode 11 and the upper electrode 13 are opposed to each other, in such a manner that the longitudinal direction of the lower electrode 11 is substantially perpendicular to the longitudinal direction of the upper electrode 13. As described by FIG. 2, the piezoelectric material is disposed in the space between the opposing lower electrode 11 and the upper electrode 13. For example, an intersection of the lower electrode 11 and the upper electrode 13 corresponds to the power generation element. Therefore, in the power-generating floor 1, the plurality of power generation elements is disposed in matrix form. A placement position of one power generation element corresponds to one block BL. In addition, the piezoelectric material may be one in a single sheet form. There may be taken a configuration in which the piezoelectric material is disposed at each of the intersections of the lower electrode 11 and the upper electrode 13.

For example, when the user U moves over position P1 of the power-generating floor 1 which is shown in FIG. 4, the power generation element of the intersection of the electrode 11i and the electrode 13h (coordinates (9, 8)) generates power. In the electrode 11i, for example, a negative charge would be generated. In the electrode 13h, for example, a positive charge would be generated.

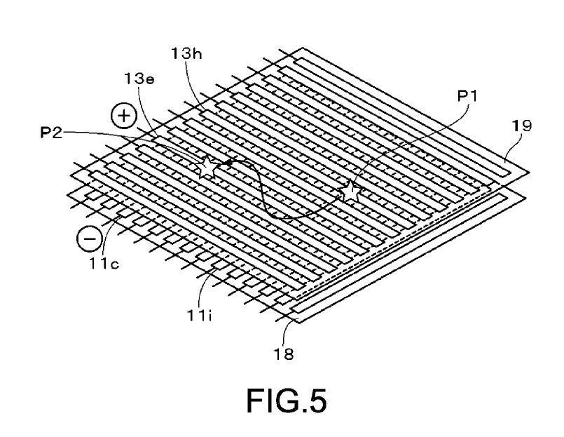

As shown in FIG. 5, a case where the user has moved from position P1 to position P2 will be described. In this case, the power generation element of the intersection of the electrode 11c and the electrode 13e (coordinates (3, 5)) generates power. In the electrode 11c, for example, a negative charge would be generated. In the electrode 13e, for example, a positive charge would be generated.

Furthermore, at the time of the user's movement from position P1 to position P2, the power generation element of each block BL where the user has passed over generates power. Therefore, by monitoring the power generation elements having generated power, there can be obtained information on at least the present position of the user and the trajectory of the movement. In the following description, trajectory of movement may also be referred to as “flow line”.

“Example of Flow Line Analysis”

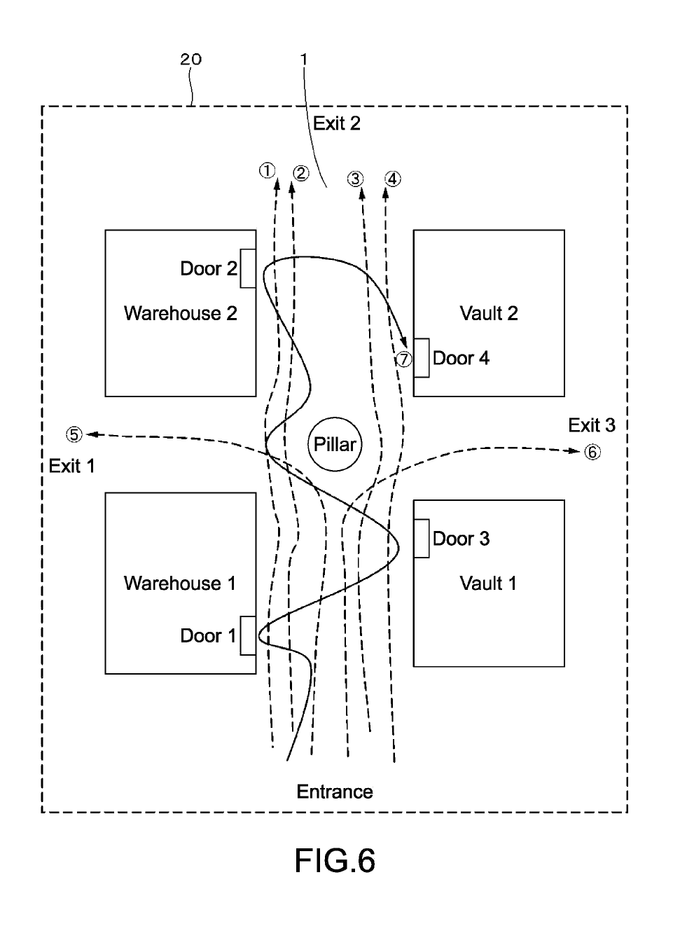

FIG. 6 shows an example of a flow line analysis. FIG. 6 is a case in which the power-generating floor 1 is laid at a floor of a predetermined space 20 in a building. An entrance to the space 20 is provided, and three exits (exit 1, exit 2 and exit 3) are also provided. In the space 20, for example, warehouse 1, warehouse 2, vault 1 and vault 2 are installed, and a pillar is provided in the center among the installations.

Each of the installations is provided with a door for preventing the intrusion of suspicious individuals and outsiders, which door is configured to be able to be locked. For example, the warehouse 1 is provided with a door 1, the warehouse 2 is provided with a door 2, the vault 1 is provided with a door 3 and the vault 2 is provided with a door 4. In addition, there may be taken a configuration in which, while the floor in the space 20 is made up as the power-generating floor 1, a floor inside each of the installations is also made up of the power-generating floor 1.

When an authorized user U, a suspicious individual and the like moved on the power-generating floor 1, the power generation element at the place where that person has moved generates power. By monitoring the history of the positions of the power generation elements having generated power, there can be obtained the flow line of the movement. In a usual case, the user U enters the space 20 from the entrance, and passes through the vicinity of the intended installation. The user, finishing things to do at the vicinity of the installation, goes out of the space 20 from the exit 1 or the like.

The user U who has things to do at the warehouse 2 enters the space 20 from the entrance and goes out of the space 20 through the exit 2 which is the nearest exit. Therefore, the flow line of the user U who has things to do at the warehouse 2 would be nearly linear patterns such as indicated by dotted lines 1 and 2. The user U who has things to do at the vault 2 enters the space 20 from the entrance and goes out of the space 20 through the exit 2. Therefore, the flow line of the user U who has things to do at the vault 2 would be nearly linear patterns such as indicated by dotted lines 3 and 4.

The user U who has things to do at the warehouse 1 enters the space 20 from the entrance and goes out of the space 20 through the exit 1. Therefore, the flow line of the user U who has things to do at the warehouse 1 would be a pattern which is bent at almost right angle to the left in the vicinity of the pillar as indicated by a dotted line 5. The user U who has things to do at the vault 1 enters the space 20 from the entrance and goes out of the space 20 through the exit 3. Therefore, the flow line of the user U who has things to do at the vault 1 would be a pattern which is bent at almost right angle to the right in the vicinity of the pillar as indicated by a dotted line 6.

The pattern of flow line associated with the possible behavior of the user U, which is usual, is stored as a normal pattern of flow line. For example, the patterns of flow lines indicated by dotted lines 1 to 6 are stored in a database. The normal patterns of flow lines may also be fed from external apparatus.

In contrast, a pattern of flow line of a suspicious individual (for example, a burglar) is different from any one of the normal patterns of flow lines. The suspicious individual, who has entered the space 20 from the entrance, attempts to break into a warehouse or vault. Therefore, the flow line of the suspicious individual becomes a pattern which meanders by way of the doors 1 to 4 as indicated by a solid line 7.

Thus, it identifies, as a suspicious individual, with respect to a person moving in a pattern that is not of the normal patterns (linear patterns, patterns which are bent in the vicinity of the pillar). For example, the person moving in the pattern of the flow line indicated by the solid line 7 may be identified as a suspicious individual. The process of discriminating the suspicious individual is performed by a discriminating apparatus.

“Configuration of Discriminating Apparatus”

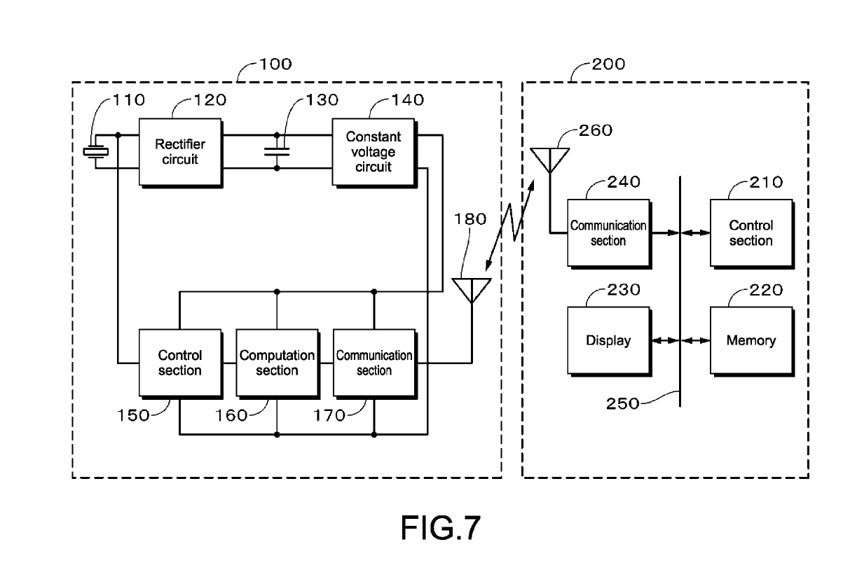

FIG. 7 shows an example of a configuration of the discriminating apparatus. A discriminating apparatus 100 includes a power generation section 110 including a plurality of power generation elements. The power generation elements are disposed in matrix form at the power-generating floor 1, as mentioned above.

The discriminating apparatus 100 is in a configuration further including a rectifier circuit 120, a power storage element 130 and a constant voltage circuit 140. For example, by the rectifier circuit 120, the power storage element 130 and the constant voltage circuit 140, a power supply section is made up. The discriminating apparatus 100 is in a configuration including a control section 150, a computation section 160, a communication section 170 and an antenna 180. It should be noted that such a configuration of the discriminating apparatus 100 is merely an example, and is not limited to the illustrated configuration. For example, the discriminating apparatus 100 may be in a configuration including an audio output device, or the like, such as speakers capable of outputting alarm sounds.

The rectifier circuit 120 is a circuit which rectifies a voltage generated in the power generation section 110. The rectifier circuit 120 is made up of diodes and diode bridges, for example.

Examples of power storage elements 130 are electric double layer capacitors, lithium ion capacitors, polyacene type organic semiconductor (polyacenic semiconductor (PAS)) capacitors, Nanogate capacitors (“Nanogate” is a registered trademark of Nanogate AG), ceramic capacitors, film capacitors, aluminum electrolytic capacitors, tantalum capacitors and the like. A composite use, where any of those are used in combination, is also possible. The power storage element 130 stores the power, with a DC (direct current) voltage which is output from the rectifier circuit 120.

The constant voltage circuit 140 is a circuit which converts an output voltage of the power storage element 130 to a predetermined voltage to stabilize the output voltage. An output voltage of the constant voltage circuit 140 would be supplied, for example, to the control section 150, the computation section 160 and the communication section 170.

Thus this is able to store the power that the power generation section 110 generates, and supply the stored power to each of the sections of the discriminating apparatus. Therefore, for example, it is possible to make it unnecessary to provide power sources such as batteries for causing the discriminating apparatus 100 to operate, and battery replacement or charging of the battery may be unnecessary. It should be noted that the present disclosure is not that it is to absolutely eliminate the use of batteries and the like, but for example, a composite use of such as secondary batteries and capacitors is also possible. Furthermore in the cases where batteries are used, by supplying the power from the power generation section 110 to each of the sections of the discriminating apparatus, the consumption of the battery can be reduced and the deterioration of the battery can be suppressed.

The control section 150 has a configuration including CPU (Central Processing Unit), for example, and is configured to control operation of each of the sections of the discriminating apparatus 100. The computation section 160 is configured to perform process for identifying suspicious individuals by using information on power generation of the power generation section 110. Memory (not shown) is connected to the computation section 160. To the memory, the normal patterns of flow lines are to be stored. The normal patterns of flow lines may also be supplied from external apparatus to the discriminating apparatus 100.

The computation section 160 compares a given pattern of flow line of a user and the normal patterns of flow lines, and makes a discrimination of whether or not the user is a suspicious individual. The feature of the computation section 160 may be built in the control section 150.

The communication section 170 is an interface for communication between the discriminating apparatus 100 and such as an external apparatus 200. The communication to be made by the communication section 170 may be either wired or wireless communication, and may also be communication via a medium such as a human body. Furthermore, for example, in the cases where amount of power generation is not sufficient for allowing the discriminating apparatus 100 to communicate to the external apparatus 200, it may be configured to communicate to the external apparatus 200 via communicating with other nearby discriminating apparatus 100. However, in this case, the discriminating apparatus 100 is provided with an ability to send and receive.

Examples of communications in wireless manner that may be used include, but are not limited to, communications using infrared ray, short-range low-power type “ANT” standard communication, “Z-Wave (registered US trademark of Zensys A/S CORPORATION)” standard communication, “Zigbee (registered trademark of ZigBee Alliance)” standard communication, “Bluetooth Low Energy (“Bluetooth” is a registered trademark of Bluetooth SIG, Inc.)” standard communication and “Wi-Fi (registered trademark of Wi-Fi Alliance)” communication that easily forms networks.

The communication section 170 is configured to perform process of modulation of data in a predetermined manner, and demodulation of received data. The data subjected to process by the communication section 170 are sent to the external apparatus 200 via the antenna 180. The data sent from the external apparatus 200 are received by the antenna 180. To the received data, the process of such as demodulation and error correction is performed by the communication section 170.

“Configuration of External Apparatus”

An example of a configuration of an external apparatus will be described. The external apparatus 200 is, for example, a security center which is provided at a position spaced from the discriminating apparatus 100. The external apparatus 200 monitors security of the place where the discriminating apparatus 100 is installed. The external apparatus 200 is in a configuration including a control section 210, a memory 220, display 230 and a communication section 240, for example. Each of these sections and the like are connected via a bus 250. The communication section 240 is connected with an antenna 260.

The control section 210 has a configuration including CPU, for example, and is configured to control operation of each of the sections of the external apparatus 200. The memory 220 is used, for example, as a work area of the control section 210. In the memory 220, programs to be executed by the control section 210, and display data to be displayed on the display 230, may be stored.

The display 230 includes, for example, a display panel such as LCD (Liquid Crystal Display) and a driver for driving a display panel. The display panel of the display 230 is a relatively large sized one. On the display 230, for example, a map based on map data is displayed, and locations of such as the discriminating apparatus 100, positions of patrolling guards, and the like are displayed.

The communication section 240 is configured to perform process of modulation of data in a predetermined manner, and demodulation of received data. The data subjected to process by the communication section 240 are sent to other apparatus via the antenna 260. For example, the data are sent to the discriminating apparatus 100 and to a terminal that the guard has. The data sent from the discriminating apparatus 100 are received by the antenna 260. For example, an abnormality annunciation signal sent from the discriminating apparatus 100 is received by the antenna 260. To the received data, the process of such as demodulation and error correction is performed by the communication section 240.

“Example of Operation of Discriminating Apparatus”

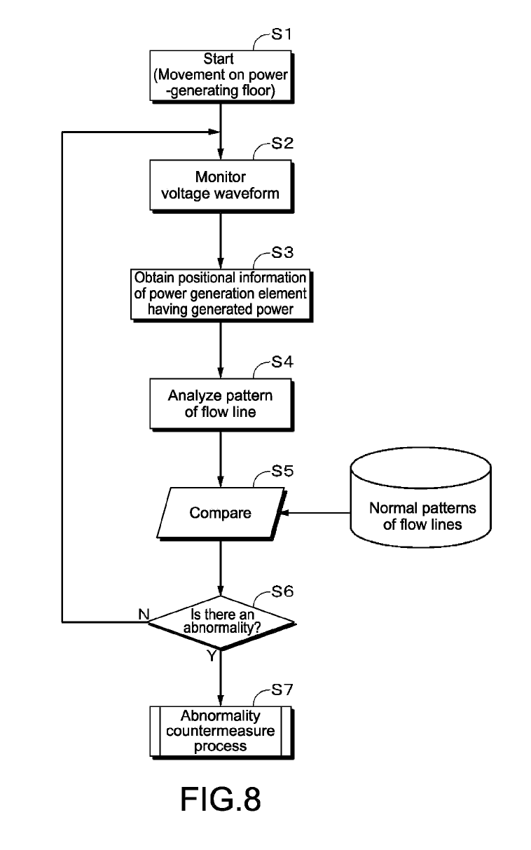

With reference to a flowchart of FIG. 8, an example of operation of the discriminating apparatus 100 will be described. A user (however, in this step, it is not yet known whether this user is an authorized user or a suspicious individual) moves on the power-generating floor 1 (step S1). With a movement of the user, the power generation element at the place where the user has moved generates power. A voltage waveform due to generation by the power generation element is fed to the computation section 160 via the control section 150. Incidentally, the voltage waveform may be digitized by the control section 150. The voltage waveform may be digitized by the computation section 160. The computation section 160 monitors the voltage waveform (step S2).

The computation section 160 identifies the position of the power generation element having generated power. Then the computation section 160 identifies the position of the power generation element having generated power to obtain its positional information (step S3). The positional information of the power generation element having generated power is an example of the information on power generation. The information on power generation may be the voltage waveform itself, and may be information to be obtained on the basis of the voltage waveform. The information on power generation may be such as, maximum level of the voltage waveform. The information on power generation may be, for example, a time interval between a timing at which the power generation element of a block BL has generated the voltage waveform and a timing at which the power generation element of a block adjacent to the block BL has generated the voltage waveform. The information on power generation may be identification information assigned to each power generation element. For example, the identification information of the power generation element whose output voltage has become equal to or greater than a certain threshold value may be used as the information on power generation.

By taking the history of the positional information of the power generation elements having generated power, a pattern of flow line of the user is analyzed (step S4). The computation section 160 reads the normal patterns of flow lines from the memory. The computation section 160 compares the normal patterns of flow lines and the pattern of the flow line of the user (step S5). This comparison process is performed in real time, for example.

By this comparison process, for example, a degree of similarity between the normal patterns of flow lines and the pattern of the flow line of the user is computed. If the computed degree of similarity is smaller than a predetermined threshold value, the user is determined to be a suspicious individual and it may be discriminated that there is an abnormality. If the computed degree of similarity is greater than the predetermined threshold value, the user is determined to be not a suspicious individual and it may be discriminated that there are no abnormalities (step S6).

If discriminated that there are no abnormalities, the process returns to step S2. In the process of step S2, for example, there is performed a monitoring of the voltage waveform generated due to another user's movement. In this case, the pattern of the flow line of the previous user may be stored to the memory as a normal pattern of flow line. Furthermore, a learning function may be provided, internally or externally, to the memory so that data of a power generation element which is not necessary for the determination may be added. If this power generation element is often active (generating power), such a power generation element may be configured to have a relay function. For example, it may have a relay function for such as signal amplification with respect to a power generation element whose transmission distance is limited due to its low amount of power generation with less opportunity to be activated. By dynamically placing such a role to the power generation elements, it is possible to streamline and optimize this system.

If discriminated that there is an abnormality, an abnormality countermeasure process is performed (step S7). The content of the abnormality countermeasure process is, for example, a process of notifying the occurrence of an abnormality to the external apparatus 200. Needless to say, the abnormality countermeasure process of such as sounding an alarm or the like may be performed in the discriminating apparatus 100.

An example of the content of the abnormality countermeasure process performed by the discriminating apparatus 100 will be described. If discriminated that an abnormality has occurred, the control section 150 or the computation section 160 generates a predetermined bit sequence signal indicating that an abnormality has occurred (hereinafter referred to as “abnormality annunciation signal” as appropriate). The abnormality annunciation signal includes location information indicating the place where the discriminating apparatus 100 is located. The generated abnormality annunciation signal is modulated by the communication section 170. The modulated abnormality annunciation signal is sent to the external apparatus 200 via the antenna 180.

The external apparatus 200 upon receiving the abnormality annunciation signal is able to; for example, give instructions such that a guard may be sent to the place where the discriminating apparatus 100 is located. Thus, it is also possible to perform the abnormality countermeasure process by the external apparatus 200.

In addition, it may also target a plurality of users in determining whether or not the user is a suspicious individual. By allowing the computation section 160 to perform the processes listed by FIG. 8 in parallel, it is possible to determine whether or not the user is a suspicious individual with respect to a plurality of users.

“Example of Operation of External Apparatus”

An example of operation of the external apparatus 200 will be described. To the external apparatus 200, for example, the abnormality annunciation signal is sent from the discriminating apparatus 100. The abnormality annunciation signal is received by the antenna 260. To the abnormality annunciation signal, the process of such as demodulation is performed by the communication section 240. The processed abnormality annunciation signal is fed to the control section 210 via the bus 250.

The control section 210 allows the display 230 to display details of the location of the discriminating apparatus 100 that has sent the abnormality annunciation signal. Further, the control section 210 instructs the guard who is present near the discriminating apparatus 100 to go to the place where the discriminating apparatus 100 is located. For example, an instruction signal including information of the location of the discriminating apparatus 100 is generated by the control section 210. To the generated instruction signal, the process of such as modulation is performed by the communication section 240. The modulated instruction signal is sent via the antenna 260.

The instruction signal is received by the guard's mobile terminal and the patrolling car. The guard is able to go to the place where the discriminating apparatus 100 is located which is indicated by the instruction signal. Thus, the abnormality countermeasure process by the external apparatus 200 is performed. A part of processes in the abnormality countermeasure process may be performed artificially.

The abnormality countermeasure process may also be performed by allowing the external apparatus 200 to remotely operate the discriminating apparatus 100. For example, in the discriminating apparatus 100, it may be configured to sound an alarm and shut the doorway of the space where the power-generating floor 1 is laid, by a remote operation performed by the external apparatus 200 to operate the discriminating apparatus 100.

### Modified Examples of First Embodiment

The first embodiment may be modified as follows, for example. In the first embodiment, a degree of similarity was to be computed by comparing the pattern of flow line of a user and the normal patterns of flow lines. However, the computation section 160 may also be configured to perform a more detailed computation.

For example, the positional information of the power generation element having generated power is obtained, and time series models of user behavior are obtained. Characteristic values such as directional distribution of the time series models are expressed by vectors, and as corresponding probabilistic state transition models, probability that their models generate a behavior to be recognized is computed by the computation section 160. For example, common behavior is expressed by high probability, and abnormal behavior is expressed by low probability. If the behavior to be recognized has high probability of being generated, it is recognized as normal common behavior pattern (for example, the patterns indicated by the dotted lines 1 to 6 in FIG. 6). If the behavior to be recognized has low probability of being generated, it is recognized as abnormal behavior pattern (for example, the pattern indicated by the solid line 7 in FIG. 6).

The power generation element is not limited to piezoelectric elements. Examples of the power generation element also include magnetostrictive elements, thermoelectric conversion elements (such as those that use the Seebeck effect, and the spin Seebeck effect), pyroelectric elements, thermoelectric power generation elements and external combustion engine (thermoacoustic power generating and Stirling engine power generating), and electromagnetic waves emitted by electronic apparatus that the user carries. Examples of generation mechanisms that generate power by electromagnetic waves emitted by apparatus for communication with the outside include those such as generators that use rectenna, electromagnetic induction, magnetic resonance or the like. The power generation element may be a hybrid-type power generation element in which one or more of these are in combination. As generation mechanisms that generate power by the actions of the user, generators that use electromagnetic induction phenomenon and electrets and the like may be mentioned. The power generation section 110 may be made up as a power generation module by combining the power generation element and a mechanical mechanism.

In addition, the information on power generation to be used for discriminating the presence or absence of an abnormality is not limited to patterns of flow lines. For example, an amount of power generation of the power generation element disposed at a predetermined block BL may be used as the information on power generation.

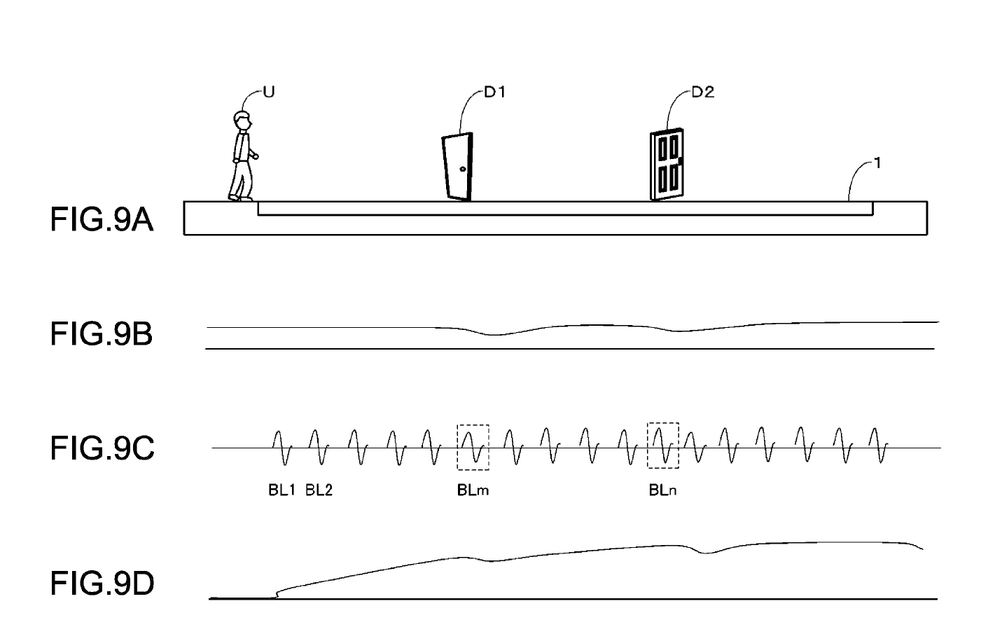

FIGS. 9A to 9D schematically show the speed of movement of the user U, and the like. The user U is not a suspicious individual. As shown in FIG. 9A, the user U moves on the power-generating floor 1. During the movement, the user U passes through the vicinity of the locked doors D1 and D2. FIG. 9B shows the speed of the movement of the user U. The speed of the user U would be substantially constant.

FIG. 9C shows the amount of power generation, or detected output, of the power generation element for each of the blocks BL. A pulse of one cycle on the amount of power generation is linked to a step length. For example, in accordance with the actions, of the user U, of stepping on a block BL1 and lifting the foot up, the power generation element disposed at the block BL1 generates power. In accordance with a pressure by being stepped on and a tension by that the foot is lifted, a positive and negative voltage waveform is observed. The amount of power generation is, for example, defined by the area surrounded by the voltage waveform. When the user U moves over the next block BL2, the power generation element disposed at the block BL2 generates power as well.

When the user U has passed over a block BLm near the door D1, the power generation element disposed at the block BLm generates power. At this time, the amount of power generation of the power generation element disposed at the block BLm is, for example, substantially equal to the amount of power generation of the power generation element disposed at the block BL1. When the user U has passed over a block BLn near the door D2, the power generation element disposed at the block BLn generates power. At this time, the amount of power generation of the power generation element disposed at the block BLn is, for example, substantially equal to the amount of power generation of the power generation element disposed at the block BL1. Thus, when the user U moves on the power-generating floor 1, the amount of power generation of the power generation element disposed at each block BL would be with less change and substantially constant.

FIG. 9D shows an example of the change in the amount of power storage of the power storage element 130. By the power generation of the power generation element disposed at the block BL on which the user moves, power is stored to the power storage element 130. By the power generation of the power generation element, the amount of power storage of the power storage element 130 would increase substantially linearly.

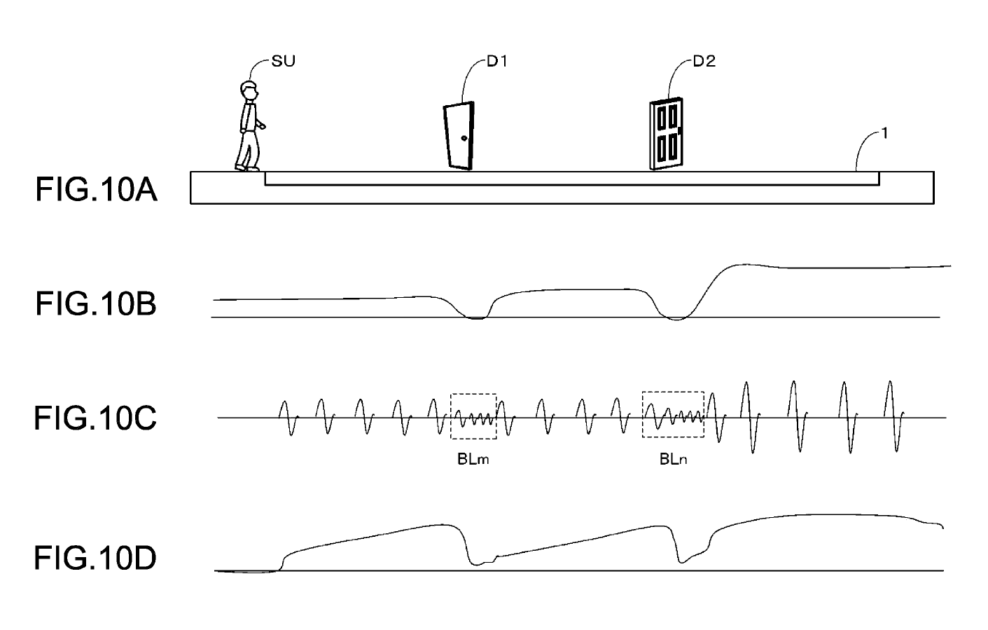

FIGS. 10A to 10D schematically show the speed of movement of a suspicious individual SU, and the like. As shown in FIG. 10A, the suspicious individual SU moves on the power-generating floor 1. During the movement, the suspicious individual SU passes by the locked doors D1 and D2. The suspicious individual SU attempts to intrude into the doors D1 and D2, destroying the locks thereof.

FIG. 10B shows the speed of the movement of the suspicious individual SU. The suspicious individual SU stops at the vicinity of the doors D1 and D2, for attempting to destroy the locks of the doors D1 and D2. Therefore, the speed in the vicinity of the doors D1 and D2 becomes almost zero.

FIG. 10C shows the amount of power generation of the power generation element of each block BL, accompanying the movement of the suspicious individual SU. A pulse of one cycle on the amount of power generation is linked to a step length. At the block BLm near the door D1, the suspicious individual SU is in the state of almost stopping. Then, the suspicious individual SU attempts to intrude into the door D1, destroying the lock thereof. The power generation element disposed at the block BLm generates minute voltages a plurality of times in accordance with the consecutive slight movement and movement by short step length, of the suspicious individual SU.

The suspicious individual SU further moves to go onto the block BLn near the door D2. At the block BLn near the door D2, the suspicious individual SU is in the state of almost stopping. Then, the suspicious individual SU attempts to intrude into the door D2, destroying the lock thereof. The power generation element disposed at the block BLn generates minute voltages a plurality of times in accordance with the consecutive slight movement and movement by short step length, of the suspicious individual SU. After that, the suspicious individual SU tries to escape. Therefore, as shown in FIG. 10B, the speed of the suspicious individual SU increases. Furthermore, the pressure by being stepped on may increase, and the amount of power generation is increased. In addition, the step length of the suspicious individual SU becomes larger, and as a result, for example, the voltage waveform may be obtained in intermittent manner such that one waveform is obtained per two blocks BL.

FIG. 10D shows an example of the change in the amount of power storage of the power storage element 130. When the suspicious individual SU is near the doors D1 and D2, the amount of power generation of the power generation element is very small. Therefore, the amount of power storage of the power storage element 130 lowers. The amount of power storage increases while the suspicious individual SU is walking or running.

Thus, the amount of power generation of the power generation element disposed at the block BLm, accompanying the movement of the user U, differs from the amount of power generation of the power generation element disposed at the block BLm accompanying the movement of the suspicious individual SU. The same applies to the power generation element of the block BLn. Therefore, by monitoring the amounts of power generation of the power generation element disposed at the block BLm and the power generation element disposed at the block BLn, it is possible to determine whether or not the user is a suspicious individual. If the amounts of power generation of the power generation elements disposed at the blocks BLm and BLn are smaller compared to the amount of power generation of other power generation elements, it may be determined that the user is likely to be a suspicious individual.

Not limited to amounts of power generation, but the voltage waveform as itself may also be monitored. For example, if the voltage waveforms at the time of power generation of the power generation elements disposed at the blocks BLm and BLn are each seen as a plurality of voltage waveforms in minute scales, it may be determined that the user is likely to be a suspicious individual. Furthermore, it may also be combined with the determination by patterns of flow lines described in the first embodiment. For example, if a pattern of flow line is different from the normal patterns, and if an amount of power generation of the power generation element disposed at the block BLm is smaller compared to the amount of power generation of other power generation elements, it may be determined that the user is likely to be a suspicious individual.

A time interval, from a timing at which the voltage waveform by the power generation element of a block BL is detected, to a timing at which the voltage waveform by the power generation element of the next block BL is detected may be used as the information on power generation. A short time for this time interval indicates a run on the power-generating floor 1. Typically, it is unusual for someone to run on the power-generating floor 1. If the time interval between the timings at which the voltage waveforms are detected is short, it may be determined that the user is likely to be a suspicious individual.

In addition, for example, when a guard is confirming the locking of each door, it is possible that the pattern of flow line of the guard is similar to the pattern of the flow line indicated by the solid line 7. Therefore, it may be configured to determine that the user is not a suspicious individual in the specific cases where the pattern of the flow line indicated by the solid line 7 is detected in a predetermined time zone for the guard to patrol. In order to obtain time information, the discriminating apparatus 100 and the external apparatus 200 may be in a configuration including RTC (Real Time Clock).

Furthermore, the external apparatus 200 such as a security center may be configured to have the feature of the computation section 160. The normal patterns of flow lines may be stored to the external apparatus 200. Still further, the external apparatus 200 may be in a configuration serving as a discriminating apparatus.

For example, when power generation elements generate power, the control section 150 digitizes the positional information of the power generation elements having generated power. A plurality of pieces of the positional information digitized is subjected to modulation process and the like by the communication section 170. The plurality of pieces of the positional information subjected to the modulation process and the like is then, for example, time-division multiplexed and sent to the external apparatus 200.

The positional information of the power generation elements is received by the external apparatus 200. The received positional information is subjected to demodulation process and the like by the communication section 240. A plurality of pieces of the positional information subjected to the modulation process and the like is fed to the control section 210 via the bus 250. The control section 210 obtains a pattern of flow line on the basis of the plurality of pieces of the positional information. Then, the control section 210 performs a comparison of the obtained pattern of flow line with the normal patterns of flow lines stored in the memory 220. In other words, the control section 210 performs the same process as the computation section 160. Thus, the discrimination of the presence or absence of an abnormality may be performed by the external apparatus 200. By allowing the external apparatus 200 to perform the discrimination of the presence or absence of an abnormality, the power consumption in the discriminating apparatus 100 can be reduced.

In a case where the external apparatus 200 receives the abnormality annunciation signal sent from the discriminating apparatus 100, the external apparatus 200 may sound an alarm, siren or the like. The external apparatus 200 may be provided with an audio output device for sounding the alarm, siren or the like. The audio output device is made up with a speaker including configurations of such as audio interfaces and amplifiers, for example.

The first embodiment is not limited to that of discriminating an intrusion of a suspicious individual, but may be also diverted to other systems. For example, the power-generating floor 1 may be laid in a house where an elderly person lives. For example, if the power generation elements of the power-generating floor 1 have not been generating power for a predetermined time (about several hours, for example), a process of checking safety of the elderly may be performed. Further, for example, in the cases where a power generation from heat is utilized, such cases may determine whether or not there is an abnormality in the target's body temperature, and whether or not the target has a heat source. The former allows it to identify a route of infection for diseases and the like, and manage entering of a person in disease. This may further enable it to appropriately control air flow and air conditioning control system, in order to prevent airborne infection from a person in disease to a person in normal health. The latter allows it to manage high-risk areas such as an area filled with reactive gas so as to keep out the target having a heat source. In the cases where a power generation from electromagnetic waves is utilized, for example, in medical front and the like where an impact of electromagnetic waves would be serious, it may perform a process of alerting.

### 2. Second Embodiment

Next, a second embodiment will be described. In the first embodiment, as an example of process of discriminating an abnormality, the presence or absence of a suspicious individual was described to be discriminated. In the second embodiment, the process of discriminating an abnormality will be described to be a process of discriminating the presence or absence of trouble that happens to a user. The trouble that happens to a user is such as sudden deconditioning of the user, a case that the user encounters a suspicious individual, and a case that the user encounters a traffic accident.

“Overview of Mobile Terminal”

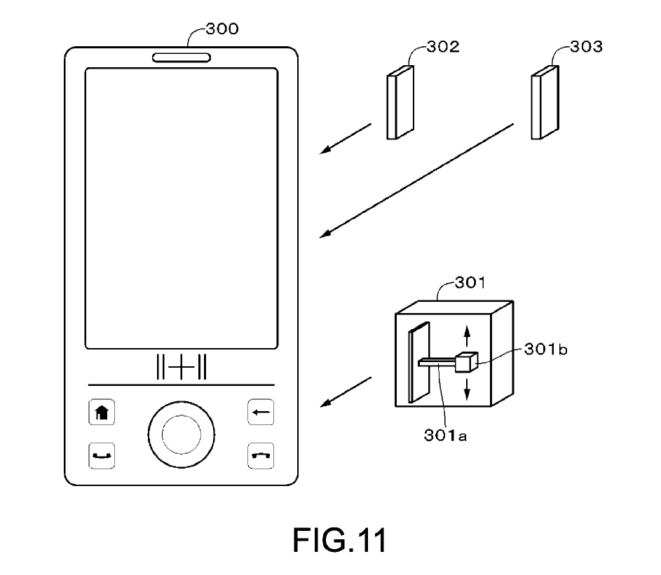

FIG. 11 shows an example of a mobile terminal, which is an example of the discriminating apparatus. A mobile terminal 300 is, for example, a mobile phone, a smartphone, a tablet computer or the like. The mobile terminal 300 is to be carried in such a manner that it is in contact with the surface of the user's body, for example. For example, a power generation section 301 which generates power by displacement due to vibrations, a heart rate sensor 302 which detects the user's heartbeat, and a sweat sensor 303 which detects sweating of the user are built in the mobile terminal 300.

However, the heart rate sensor 302 and the sweat sensor 303 may not necessarily be built in the mobile terminal 300. Either or both of the heart rate sensor 302 and the sweat sensor 303 may be worn on the user's body independently from the mobile terminal 300. It may be configured such that sensor information obtained by the heart rate sensor 302 and the sweat sensor 303 is to be fed to the mobile terminal 300 via wireless communication, wired communication or body area network communication.

The power generation section 301 has a piezoelectric element 301a (including electrodes to detect a voltage from the piezoelectric element) in a rod shape, for example. The piezoelectric element 301a is, for example, a cantilever having one end fixed. To a free end of the piezoelectric element 301a, there is attached a weight 301b. The weight 301b is caused to vibrate horizontally or vertically, depending on a shake of the mobile terminal 300. By the vibrations of the weight 301b, the piezoelectric element 301a is displaced and thus the piezoelectric element 301a generates power.

“Example of Configuration of Mobile Terminal”

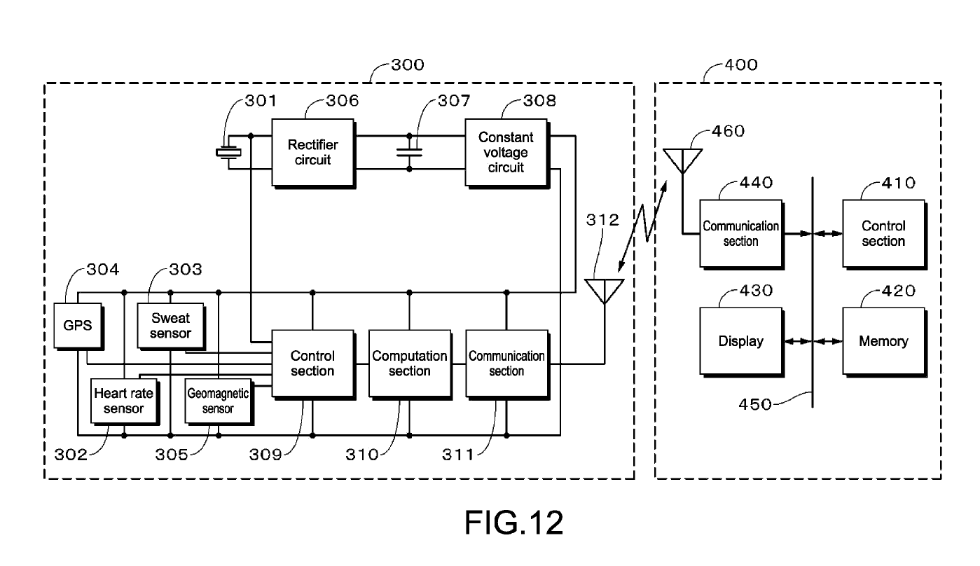

FIG. 12 shows an example of major configuration of the mobile terminal 300. The mobile terminal 300 is capable of communicating with an external apparatus 400 and the like, as will be described later. The external apparatus 400 is a host center, a security center or the like. The mobile terminal 300 includes the power generation section 301. The power generation section 301 is made up with a piezoelectric element (such as monomorph, bimorph and stacked types).

The power generation section 301 is not limited to piezoelectric elements. Examples of the power generation section 301 also include magnetostrictive elements, thermoelectric conversion elements (such as those that use the Seebeck effect, and the spin Seebeck effect) which may generate power with the change in temperature of the surface of the user's body, pyroelectric elements, thermoelectric power generation elements and external combustion engine (thermoacoustic power generating and Stirling engine power generating), and electromagnetic waves emitted by electronic apparatus that the user carries. Examples of generation mechanisms that generate power by electromagnetic waves emitted by apparatus for communication with the outside include those such as generators that use rectenna, electromagnetic induction, magnetic resonance or the like. The power generation element may be a hybrid-type power generation element in which one or more of these are in combination. As generation mechanisms that generate power by the actions of the user, generators that use electromagnetic induction phenomenon and electrets and the like may be mentioned. The power generation section 301 may be made up as a power generation module by combining the power generation element and a mechanical mechanism.

The mobile terminal 300 is in a configuration further including a rectifier circuit 306, a power storage element 307 and a constant voltage circuit 308. For example, by the rectifier circuit 306, the power storage element 307 and the constant voltage circuit 308, a power supply section is made up. The mobile terminal 300 is in a configuration including a control section 309, a computation section 310, a communication section 311 and an antenna 312.

The mobile terminal 300 has the heart rate sensor 302 and the sweat sensor 303 as sensors that detect a body situation of the user. The heart rate sensor 302 is configured to obtain the mobile terminal 300 user's heart rate. The sweat sensor 303 is configured to obtain the mobile terminal 300 user's sweat rate. By monitoring such sensor information obtained by these sensors, for example, it is possible to use the mobile terminal 300 to manage the health of the user.

If the heart rate obtained by the heart rate sensor 302 is not normal, for example, the user is likely to be in an unstable mental state such as being astonished. If the value of the sweat sensor 303 is not normal, for example, it may be assumed that the user is in troubled physical condition and mental state, such as, the state of being in a cold sweat.

The mobile terminal 300 includes a GPS (Global Positioning System) sensor 304 configured to obtain the location of the mobile terminal 300, and a geomagnetic sensor 305 configured to detect the direction of movement of the mobile terminal. The mobile terminal 300 may also be in a configuration including one or more of acceleration sensors and gyro sensors. The state of the user's action may be detected by using the acceleration sensor or the gyro sensor. The positional information of the mobile terminal 300 obtained by the GPS sensor 304 is sent to the external apparatus 400 periodically, for example.

The heart rate sensor 302, the sweat sensor 303, the GPS sensor 304 and the geomagnetic sensor 305 will collectively be referred to as “sensor section” as appropriate. It should be noted that it is not necessary that all the sensors of the illustrated are to be included in the mobile terminal 300. There may also be taken a configuration in which the mobile terminal 300 includes some part of the sensors of the illustrated.

Such a configuration of the mobile terminal 300 is merely an example, and is not limited to the illustrated configuration. For example, the mobile terminal 300 may be in a configuration including an audio output device, or the like, such as speakers capable of outputting alarm sounds, sirens or “SOS” signals. The mobile terminal 300 may be provided with such as a sensor which measures brain waves. It should be noted that in FIG. 12, graphical representations regarding some part of configuration such as a display and an operation section are omitted as appropriate.

The rectifier circuit 306 is a circuit which rectifies a voltage generated in the power generation section 301. The rectifier circuit 306 is made up of diodes and diode bridges, for example.

Examples of power storage elements 307 are electric double layer capacitors, lithium ion capacitors, PAS capacitors, Nanogate capacitors, ceramic capacitors, film capacitors, aluminum electrolytic capacitors, tantalum capacitors and the like. The power storage element 307 stores the power, with a DC voltage which is output from the rectifier circuit 306.

The constant voltage circuit 308 is a circuit which converts an output voltage of the power storage element 307 to a predetermined voltage to stabilize the output voltage. An output voltage of the constant voltage circuit 308 would be supplied, for example, to the control section 309, the computation section 310, the communication section 311 and the sensor section.

This is able to store the power that the power generation section 301 generates, and supply the stored power to each of the sections of the mobile terminal 300. Therefore, for example, it is possible to make it unnecessary to provide power sources such as batteries for causing the mobile terminal 300 to operate, and battery replacement or charging of the battery may be unnecessary. It should be noted that the present disclosure is not that it is to absolutely eliminate the use of batteries. Furthermore in the cases where batteries are used, by supplying the power from the power generation section 301 to each of the sections of the mobile terminal 300, the consumption of the battery can be reduced and the deterioration of the battery can be suppressed.

The control section 309 has a configuration including CPU, for example, and is configured to control operation of each of the sections of the mobile terminal 300. Information on power generation from the power generation section 301 is fed to the control section 309. Further, the sensor information from the sensor section is fed to the control section 309. The control section 309 is configured to feed the information on power generation and the sensor information to the computation section 310. The information on power generation and the sensor information may be digitized by the control section 309.

The computation section 310 is configured to detect, for example, the sudden deconditioning of a user, by using information on power generation of the power generation section 301 and the sensor information. It may also be configured to detect the sudden deconditioning of the user by using either one of the information on power generation and the sensor information. For example, an amount of metabolic heat may be monitored on the basis of the amount of power generation from a power generation section that generates power in accordance with quantity of heat passing through its element (as a power generation element). Furthermore, the information on power generation and the sensor information may be used for detection with good precision.

Memory (not shown) is connected to the computation section 310. To the memory, patterns of the user's heart rate range and sweat rate, regarding the user in the normal state, are to be stored. The computation section 310 compares the sensor information from such as the heart rate sensor 302 with the normal patterns. Further, it makes a discrimination of whether or not there is an occurrence of sudden deconditioning of the user, using the information on power generation of the power generation section 301. The feature of the computation section 310 may be built in the control section 309.

The communication section 311 is an interface for communication between the mobile terminal 300 and such as the external apparatus 400. The communication to be made by the communication section 311 may be either wired or wireless communication, and may also be communication via a medium such as a human body.

Examples of communications in wireless manner that may be used include, but are not limited to, communications using infrared ray, short-range low-power type “ANT” standard communication, “Z-Wave” standard communication, “Zigbee” standard communication, “Bluetooth Low Energy” standard communication and “Wi-Fi” communication that easily forms networks.

The communication section 311 is configured to perform process of modulation of data in a predetermined manner, and demodulation of received data. The data subjected to process by the communication section 311 are sent to the external apparatus 400 and the like via the antenna 312. The data sent from the external apparatus 400 are received by the antenna 312. To the received data, the process of such as demodulation and error correction is performed by the communication section 311.

From the mobile terminal 300 to the external apparatus 400, for example, there is sent an emergency signal indicating that a trouble has happened to the user. The destination of the emergency signal is not limited to the external apparatus 400. For example, the emergency signal may be sent to a mobile terminal which is registered in advance. When the external apparatus 400 or the like receives the emergency signal, for example, the external apparatus 400 transmits information to the mobile terminal 300 and checks the safety of the user. If the safety of the user is not able to be confirmed, an abnormality countermeasure process such as dispatching a guard to a place that corresponds to the positional information sent from the mobile terminal 300 is performed.

“Example of Configuration of External Apparatus”

The external apparatus 400 is, for example, a security center. The external apparatus 400 may be such as a host center and a hospital. The external apparatus 400 may be a mobile terminal. The mobile terminal is carried by a security firm's guard, for example. The external apparatus 400 is in a configuration including a control section 410, a memory 420, display 430 and a communication section 440, for example. Each of these sections and the like are connected via a bus 450. The communication section 440 is connected with an antenna 460.

The control section 410 has a configuration including CPU, for example, and is configured to control operation of each of the sections of the external apparatus 400. The memory 420 is used, for example, as a work area of the control section 410. In the memory 420, programs to be executed by the control section 410, and display data to be displayed on the display 430, may be stored.

The display 430 includes, for example, a display panel such as LCD and a driver for driving a display panel. The display panel of the display 430 is a relatively large sized one. On the display 430, for example, a map based on map data is displayed, and locations of such as the mobile terminal 300, positions of patrolling guards, and the like are displayed.

The communication section 440 is configured to perform process of modulation of data in a predetermined manner, and demodulation of received data. The data subjected to process by the communication section 440 are sent to other apparatus via the antenna 460. For example, the data are sent to the mobile terminal 300 and to a terminal that the guard has. The data sent from the mobile terminal 300 are received by the antenna 460. For example, an emergency signal sent from the mobile terminal 300 and the positional information of the mobile terminal is received by the antenna 460. To the received emergency signal and the positional information, the process of such as demodulation and error correction is performed by the communication section 440. The external apparatus 400 is able to obtain the location, where the mobile terminal 300 is, on the basis of the positional information sent from the mobile terminal 300.

The external apparatus 400 may be in a configuration including RTC for obtaining time information. The external apparatus 400 may be in a configuration with an audio output device which may include such as audio interfaces, amplifiers and speakers. Thus, the configuration of the external apparatus 400 may be modified as appropriate.

Upon receiving the emergency signal from the mobile terminal 300, the external apparatus 400 performs the abnormality countermeasure process. The abnormality countermeasure process is, for example, that transmits information to the mobile terminal 300 and checks the safety of the user of the mobile terminal 300. If the safety of the user of the mobile terminal 300 is not able to be confirmed, the external apparatus 400 performs process such as dispatching a guard or a doctor to the place that corresponds to the positional information of the mobile terminal 300.

“Example of Process by Mobile Terminal”

An example of process by the mobile terminal 300 will be described. First, a process of discriminating a case of sudden deconditioning of the mobile terminal 300 user will be described. Incidentally, in the memory that is provided on the computation section 310, there are data of heart rate and sweat rate, regarding the user in a state of good health (normal state), stored in advance. The heart rate and sweat rate may be set by the user, or may also be set by that the mobile terminal 300 is configured to learn them.

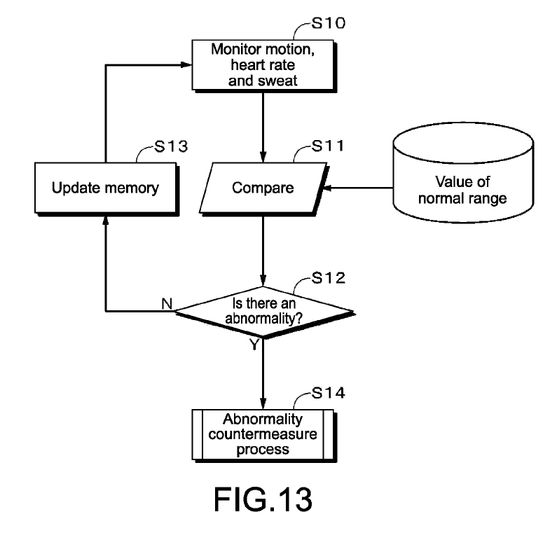

With reference to a flowchart of FIG. 13, an example of flow of process will be described. The mobile terminal 300 is carried by a user, and the user's heart rate is detected by the heart rate sensor 302 of the mobile terminal 300. Further, the user's sweat rate is detected by the sweat sensor 303. Data indicating the heart rate and the sweat rate are fed to the control section 309 in real time. The control section 309 converts the data indicating the heart rate and the sweat rate into digital signals, for example. The data indicating the heart rate and the sweat rate are monitored by the computation section 310 (step S10).

The power generation section 301 generates power in accordance with a shake of the mobile terminal 300. A voltage waveform which is generated due to the power generation by the power generation section 301 is fed to the control section 309. The control section 309 digitizes the voltage waveform that has been fed, for example. The digitized voltage data, being an example of data indicating motion, are fed to the computation section 310. The computation section 310 monitors the voltage data, along with the data indicating the heart rate and the sweat rate (step S10). In addition, the positional information of the mobile terminal 300 detected by the GPS sensor 304 is sent to the external apparatus 400 periodically.

The computation section 310 reads from the memory the value of normal range for the heart rate and the sweat rate. Then, the computation section 310 determines whether or not the data of the heart rate and the sweat rate, fed from the control section 309, are in the value of the normal range (step S11). For example, if the data of the heart rate and the sweat rate are not in the value of the normal range, the presence or absence of the voltage data would be determined. At this time, if the mobile terminal 300 has not been shaken, that is, if there is no motion of the user, the voltage data would be almost undetected. In such a case that the data of the heart rate and the sweat rate are not in the value of the normal range, and in which case the voltage data are not present, the computation section 310 determines that the mobile terminal 300 user is not in normal physical condition, and thus, it determines that there is an abnormality (step S12).

If determined that there is an abnormality, the mobile terminal 300 performs an abnormality countermeasure process (step S14). For example, an emergency signal in a predetermined format is generated by the control section 309 of the mobile terminal 300, and the emergency signal is sent to the external apparatus 400 and the like via the communication section 311 and the antenna 312. The external apparatus 400 performs the abnormality countermeasure process in response to the emergency signal. For example, it transmits information to the mobile terminal 300 to check the safety of the user of the mobile terminal 300. If the safety of the user is not able to be confirmed, it performs process to dispatch a guard or a doctor to the place that corresponds to the positional information sent from the mobile terminal 300. The processes in abnormality countermeasure process carried out by the external apparatus 400 may all be performed automatically, or may also have a part to be performed artificially.

If determined that there are no abnormalities, the content in the memory of the computation section 310 is to be updated as appropriate (step S13), and the monitoring of the heart rate and the like would be performed again.

Thus, in the case where the heart rate and the sweat rate is not normal, and is with almost no motion of the user, it is determined that the sudden deconditioning of the user has occurred. In such a case, even if the user does not perform any operations by oneself, it is able to send the emergency signal to the external apparatus 400. In addition, the abnormality countermeasure process to be performed by the mobile terminal 300 is not limited to process of sending emergency signals. For example, a process of asking for help to the surrounding, reproducing the sound to call for help from the mobile terminal 300, may be performed.

In addition, if the voltage data have not been observed for a predetermined time (about ten minutes, for example), a process of determining whether or not the heart rate and the sweat rate is in the value of the normal range may be performed. By making a determination using the sensor information and the information on power generation in combination, it is able to improve accuracy of the process of determining an abnormality regarding the user.

### Modified Examples of Second Embodiment

The second embodiment may be modified as follows, for example. For example, as the sensor information, the positional information to be obtained by the GPS sensor 304 and the information of the geomagnetic sensor 305 may be used. Further, the sensor information may be the information itself that is fed from each sensor, and may be information to be obtained by performing a predetermined computation on the information being fed from each sensor.

The computation section 310 discriminates a short interval in power generation by the power generation section 301 to be a case of that the user is running. The computation section 310 obtains the change in direction of movement of the user, from the sensor information obtained by the geomagnetic sensor 305. For example, if the user is running or in the state with frequent strenuous changes in direction of movement, and if at least one of the heart rate and the sweat rate indicates an abnormality, the computation section 310 determines that the user has encountered a suspicious individual and is taking evasive action to escape from the suspicious individual. In such a case, the mobile terminal 300 may also sound a buzzer for security, and may send an emergency signal. In addition, it is possible that the combination of the information on power generation and the sensor information in the discrimination of the presence or absence of an abnormality may be modified as appropriate.

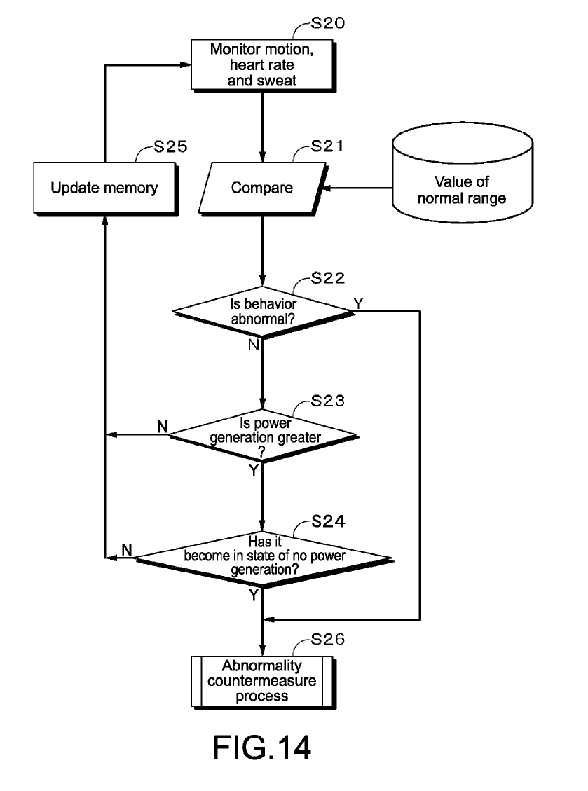

As an example of the trouble that happens to a user, a case of when the user encounters a traffic accident will be described with reference to a flowchart of FIG. 14. In the mobile terminal 300, the change in positional information of the user can be known from the information obtained by the GPS sensor 304. From the degree of change thereof, there is obtained information on the change in speed of the user. Further, from the information obtained by the geomagnetic sensor 305, there is obtained information on the change in direction of movement of the user. The information on the change in speed of the user and the information on the change in direction of movement of the user would be obtained as information on the user's motion. In addition, to the memory that is provided on the computation section 310, the value of normal range regarding the information on the motion is stored.

The information on the motion, the heart rate and the sweat rate are monitored by the computation section 310 (step S20). Then, a comparison of such information with the value of normal range is performed (step S21). At this time, for example, if at least one of the change in speed and the change in direction of movement is not in the normal range, and also if at least one of the heart rate and the sweat rate is not in the normal range, it is determined that an abnormality has occurred to the user (step S22). In addition, how to combine the parameters of the change in speed and the like, for determining an abnormality, may be modified as appropriate. If determined that there is an abnormality, there is performed the abnormality countermeasure process such as the process of sending an emergency signal and the process of reproducing the sound to call for help to the surrounding (step S26).

In step S22, if there are no abnormalities regarding the user, the maximum level of the voltage waveform which is generated due to the power generation by the power generation section 301 is measured by the computation section 310. There is determined whether or not the maximum level of the voltage waveform is greater than a threshold value (step S23). If the maximum level of the voltage waveform is not greater than a predetermined threshold value, the content in the memory of the computation section 310 is to be updated as appropriate (step S25). Then, the monitoring of the information on the motion and the like would be performed (step S20).

If the maximum level of the voltage waveform is greater than the threshold value, the process goes on to step S24. The maximum level of the voltage waveform being greater than the threshold value indicates that there has been a strong shock to the user carrying the mobile terminal 300. For example, it may be assumed that such as a car or a bicycle has collided against the user. Incidentally, such as experiments in which a collision of a predetermined level is applied to the power generation section 301 are made in advance, and the threshold value is determined appropriately in accordance with such as results of the experiments.

There is determined whether or not the power generation section 301 has become in a state of no power generation (step S24). The “state of no power generation” has a meaning that includes a state in which the power generation section 301 does not generate power, and also a case in which the power generation section 301 generates power in only a very small level. If not in the state of no power generation, the content in the memory is to be updated as appropriate (step S25). If the power generation section 301 is in the state of no power generation, the abnormality countermeasure process is to be performed (step S26).

From that the result of the determination in step S23 is “yes”, it may be assumed that there has been a strong shock to the user. Furthermore, from that the result of the determination in step S24 is “yes”, it may be assumed that the mobile terminal 300 almost does not vibrate, that is, the user has become in a state of almost not moving. Thus, the computation section 310 determines that the user has encountered a traffic accident or taken a damage by such as falling from the stairs and has become in a state where the user is not able to move.

In such a case, for example, the abnormality countermeasure process of such as reproducing the sound to call for help to the surrounding and sending an SOS signal to the external apparatus 400 is performed. Even if the user has become in a state where the user is not able to move because of encountering a traffic accident, falling from the stairs, or the like, it is able to call for help to the surrounding and the external apparatus 400 automatically.

In addition, in the process of step S23, an amount of change of the maximum level of the voltage waveform may be observed. If the amount of change of the maximum level of the voltage waveform is greater than a predetermined threshold value, it indicates that the maximum level of the voltage waveform has instantaneously increased. In such a case, it may be determined that there has been a strong shock to the user carrying the mobile terminal 300.

There may also be used some other sensors as the sensor. For example, a body temperature sensor may be used. For example, if a high temperature is obtained by the body temperature sensor, it may be determined that the user is moving strenuously. Further, if a lower temperature than a usual body temperature is obtained by the body temperature sensor, it may be determined that the user's body temperature is dropping and there is an occurrence of an abnormality in the user's physical condition. In addition, as the abnormality in the physical condition in this case, it may include a determination of normal and abnormal psychogenic conditions regarding stress and the like.

It may be configured such that the history of the sensor information obtained from the heart rate sensor 302 and the like of the mobile terminal 300 is to be stored. It is also possible that the mobile terminal 300 is used as equipment to notify the appropriate amount of exercise or equipment for health management. Further, it may be configured such that the abnormality countermeasure process is performed in the cases where the state of no power generation has sustained for a certain period of time.

The mobile terminal 300 may send the information on power generation and the sensor information to the external apparatus 400. It may be configured such that the external apparatus 400 uses the information on power generation and the sensor information and discriminate an abnormality that occurs with the mobile terminal 300 user. The external apparatus 400 may be made to function as a discriminating apparatus.

### 3. Third Embodiment

Next, a third embodiment will be described. The third embodiment is an example of discriminating an abnormality that occurs with a vehicle such as an automobile.

“Overview of Third Embodiment”

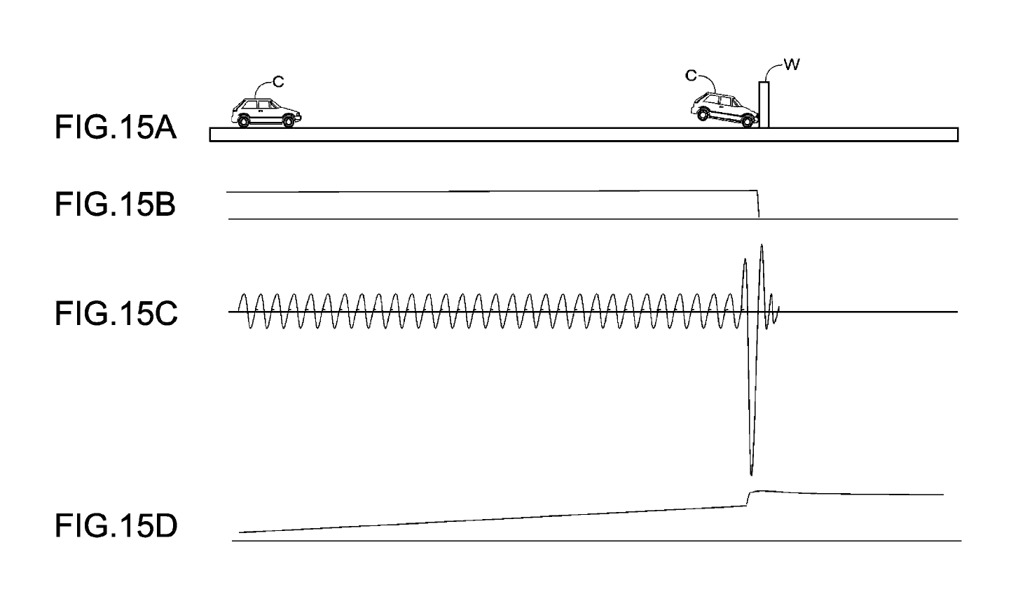

Using FIGS. 15A to 15D, an overview of the third embodiment will be described. As shown in FIG. 15A, a vehicle C travels on a road. In a predetermined place of the road, a wall W is provided upright. There is assumed that the vehicle C collides with the wall W due to such as driving error of the driver of the vehicle C.

FIG. 15B shows the speed of the vehicle C. For example, the vehicle C travels at a speed which is substantially constant. In the case where the vehicle C collides with the wall W and has caused an accident, the vehicle C becomes incapable of travelling and the speed of the vehicle C becomes almost zero.

FIG. 15C shows the amount of power generation, of a power generation section that the vehicle C has, or detected output of the power generation section. The power generation section generates power at a level which is substantially constant in accordance with vibrations that accompanies the traveling of the vehicle C. If the vehicle C collides with the wall W, the amount of power generation of the power generation section of the vehicle C instantaneously increases by a big shock due to the collision. Since the vehicle C becomes in a state of stopping, after the collision, the amount of power generation of the power generation section becomes almost zero.

FIG. 15D shows the amount of power storage of a power storage element that the vehicle C has. In accordance with the traveling of the vehicle C, the power generation section generates power, and power is stored to the power storage element. The amount of power storage of the power storage element increases in substantially linear manner, for example. In addition, although the amount of power storage almost does not change after the vehicle has collided with the wall, there may sometimes be seen a decrease in the amount of power storage due to discharge of the power storage element.

“Example of Configuration of Vehicle Apparatus”

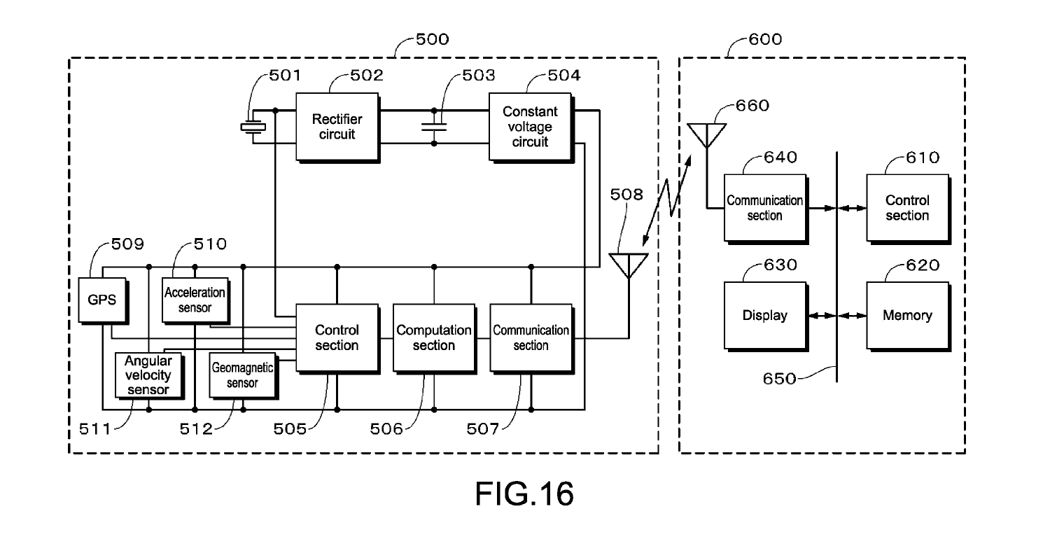

FIG. 16 shows an example of major configuration of a vehicle apparatus, which vehicle apparatus is an example of the discriminating apparatus. A vehicle apparatus 500 is an apparatus to be installed in the above-mentioned vehicle C, for example. The vehicle apparatus 500 is capable of communicating with an external apparatus 600 and the like, as will be described later. The external apparatus 600 is a traffic management center, a security center or the like. The external apparatus 600 may be a mobile terminal.

The vehicle apparatus 500 includes a power generation section 501. The power generation section 501 is made up with a piezoelectric element (such as monomorph, bimorph and stacked types). The power generation section 501 generates power in accordance with vibrations that accompanies the traveling of the vehicle C.

The power generation section 501 is not limited to piezoelectric elements. Examples of the power generation section 501 also include magnetostrictive elements, thermoelectric conversion elements (such as those that use the Seebeck effect, and the spin Seebeck effect) which may generate power with the difference or change in temperature of such as body surface, exhaust system, cooling system and engine room of the vehicle C, pyroelectric elements, thermoelectric power generation elements and external combustion engine (thermoacoustic power generating and Stirling engine power generating), and electromagnetic waves emitted by electronic apparatus and by some movable parts. Examples of generation mechanisms that generate power by electromagnetic waves emitted by apparatus for communication with the outside include those such as generators that use rectenna, electromagnetic induction, magnetic resonance or the like. The power generation element may be a hybrid-type power generation element in which one or more of these are in combination. As generation mechanisms that generate power by the actions of the user, generators that use electromagnetic induction phenomenon and electrets and the like may be mentioned. The power generation section 501 may be made up as a power generation module by combining the power generation element and a mechanical mechanism.

The power generation section 501 is attached to the vicinity of the suspension of the vehicle C, for example. By the vibrations transmitted to the suspension, the power generation section 501 vibrates and thus generates power. The power generation section 501 has its length, shape and weight to be defined in such a manner that it may have a resonance frequency that substantially coincides with the vibration frequency to be generated in accordance with the traveling of the vehicle C. Furthermore, considering the vibration frequency at the position where the power generation section 501 is attached, the resonance frequency of the power generation section 501 is adjusted. For example, the vibration frequencies differ between a case in which the power generation section 501 is attached onto a spring of the suspension and a case in which the power generation section 501 is attached to such as an axle below the spring of the suspension. Taking into account the difference in the vibration frequencies of the attachment location, the resonance frequency of the power generation section 501 is set appropriately.

The vehicle apparatus 500 is in a configuration further including a rectifier circuit 502, a power storage element 503 and a constant voltage circuit 504. For example, by the rectifier circuit 502, the power storage element 503 and the constant voltage circuit 504, a power supply section is made up. The vehicle apparatus 500 is in a configuration including a control section 505, a computation section 506, a communication section 507 and an antenna 508.

The vehicle apparatus 500 has a GPS sensor 509, an acceleration sensor 510, an angular velocity sensor 511 and a geomagnetic sensor 512, for example, as sensors that detect situation of the vehicle C. It is not necessary that all the sensors of the illustrated are to be included in the vehicle apparatus 500. There may also be taken a configuration in which the vehicle apparatus 500 includes some part of the sensors of the illustrated.

The GPS sensor 509 obtains the positional information of the vehicle C. The acceleration sensor 510 obtains the acceleration of the vehicle C by such as forces acting on the vehicle C. The angular velocity sensor (gyro sensor) 511 obtains the change in attitude from the initial direction of the vehicle C. The geomagnetic sensor 512 obtains the change in direction of movement of the vehicle C. Such sensor information obtained by these sensors is fed to the control section 505. The GPS sensor 509, the acceleration sensor 510, the angular velocity sensor 511 and the geomagnetic sensor 512 may collectively be referred to as “sensor section” as appropriate.

The rectifier circuit 502 is a circuit which rectifies a voltage generated in the power generation section 501. The rectifier circuit 502 is made up of diodes and diode bridges, for example.

Examples of power storage elements 503 are electric double layer capacitors, lithium ion capacitors, PAS capacitors, Nanogate capacitors, ceramic capacitors, film capacitors, aluminum electrolytic capacitors, tantalum capacitors and the like. The power storage element 503 stores the power, with a DC voltage which is output from the rectifier circuit 502.

The constant voltage circuit 504 is a circuit which converts an output voltage of the power storage element 503 to a predetermined voltage to stabilize the output voltage. An output voltage of the constant voltage circuit 504 would be supplied, for example, to the control section 505, the computation section 506, the communication section 507 and the sensor section.

This is able to store the power that the power generation section 501 generates, and supply the stored power to each of the sections of the vehicle apparatus 500. Therefore, for example, it is possible to make it unnecessary to provide batteries for causing the vehicle apparatus 500 to operate, and battery replacement or charging of the battery may be unnecessary. It should be noted that the present disclosure is not that it is to absolutely eliminate the use of batteries. In the vehicle apparatus 500, in practice, a rechargeable secondary battery is used. However, even when the batteries are used, since the power from the power generation section 501 is to be supplied to each of the sections of the vehicle apparatus 500, the consumption of the battery can be reduced and the deterioration of the battery can be suppressed.

The control section 505 has a configuration including CPU, for example, and is configured to control operation of each of the sections of the vehicle apparatus 500. The control section 505 performs exchange of data and commands with each of the sections of the vehicle apparatus 500, for example, through a CAN (Controller Area Network) communication. Information on power generation from the power generation section 501 is fed to the control section 505. Further, the sensor information from the sensor section is fed to the control section 505. The control section 505 converts the information on power generation and the sensor information into a digital signal, as appropriate, and feeds the digitized information on power generation and the sensor information to the computation section 506.

The computation section 506 determines whether or not the vehicle C has caused an accident, using the information on power generation fed from the power generation section 501, for example. If determined that the vehicle C has caused an accident, it generates a notification signal indicating that the vehicle C has caused an accident. The computation section 506 feeds the generated notification signal to the control section 505. The feature of the computation section 506 may be built in the control section 505.

The communication section 507 is an interface for communication between the vehicle apparatus 500 and such as the external apparatus 600. The communication to be made by the communication section 507 uses a wireless method, for example. Examples of communications in wireless manner that may be used include communications using infrared ray, short-range low-power type “ANT” standard communication, “Z-Wave” standard communication, “Zigbee” standard communication, “Bluetooth Low Energy” standard communication and “Wi-Fi” communication that easily forms networks. Needless to say, the communication is not limited to those based on these standards or methods.

The communication section 507 is configured to perform process of modulation of data in a predetermined manner, and demodulation of received data. The data subjected to process by the communication section 507 are sent to the external apparatus 600 and the like via the antenna 508. The data sent from the external apparatus 600 are received by the antenna 508. To the received data, the process of such as demodulation and error correction is performed by the communication section 507.

Such a configuration of the vehicle apparatus 500 is merely an example, and is not limited to the illustrated configuration. It should be noted that in FIG. 16, graphical representations of such as car audio, a configuration relating to car navigation, and configurations relating to operations such as a handle and a lever are omitted as appropriate.

The computation section 506 of the vehicle apparatus 500 determines whether or not the vehicle C has caused an accident, in accordance with the information on power generation of the power generation section 501. If determined that the vehicle C has caused an accident, the computation section 506 feeds notification signal to the control section 505. The control section 505 generates an emergency signal in response to the notification signal. The control section 505 sends the emergency signal to the external apparatus 600 via the communication section 507 and the antenna 508.

“Example of Configuration of External Apparatus”

The external apparatus 600 is, for example, a security center or a traffic management center. The external apparatus 600 may be such as a police station. The external apparatus 600 may be a mobile terminal. The mobile terminal is, for example, a mobile terminal which is registered by the vehicle apparatus 500 in advance. The external apparatus 600 is in a configuration including a control section 610, a memory 620, display 630 and a communication section 640, for example. Each of these sections and the like are connected via a bus 650. The communication section 640 is connected with an antenna 660.

The control section 610 has a configuration including CPU, for example, and is configured to control operation of each of the sections of the external apparatus 600. The memory 620 is used, for example, as a work area of the control section 610. In the memory 620, programs to be executed by the control section 610, and display data to be displayed on the display 630, may be stored.

The display 630 includes, for example, a display panel such as LCD and a driver for driving a display panel. The display panel of the display 630 is a relatively large sized one. On the display 630, for example, a map based on map data is displayed. Locations of the vehicle C and the like are displayed superimposed on the map.

The communication section 640 is configured to perform process of modulation of data in a predetermined manner, and demodulation of received data. The data subjected to process by the communication section 640 are sent to other apparatus via the antenna 660. For example, the data are sent to the vehicle apparatus 500. The data sent from the vehicle apparatus 500 are received by the antenna 660. For example, an emergency signal sent from the vehicle apparatus 500 and the positional information of the vehicle apparatus 500 is received by the antenna 660. To the received emergency signal and the positional information, the process of such as demodulation and error correction is performed by the communication section 640. The external apparatus 600 is able to obtain the location, where the vehicle apparatus 500 is, on the basis of the positional information sent from the vehicle apparatus 500.

The external apparatus 600 may be in a configuration including RTC for obtaining time information. It may be in a configuration with an audio output device which may include such as audio interfaces, amplifiers and speakers. Thus, the configuration of the external apparatus 600 may be modified as appropriate.

Upon receiving the emergency signal from the vehicle apparatus 500, the external apparatus 600 performs the abnormality countermeasure process. The abnormality countermeasure process is a process to dispatch a traffic management personnel and the like to the place that corresponds to the positional information of the vehicle apparatus 500, and a process to notify other users by such as broadcasting that there is an accident occurred at the place that corresponds to the positional information of the vehicle apparatus 500.

“Example of Process by Vehicle Apparatus”

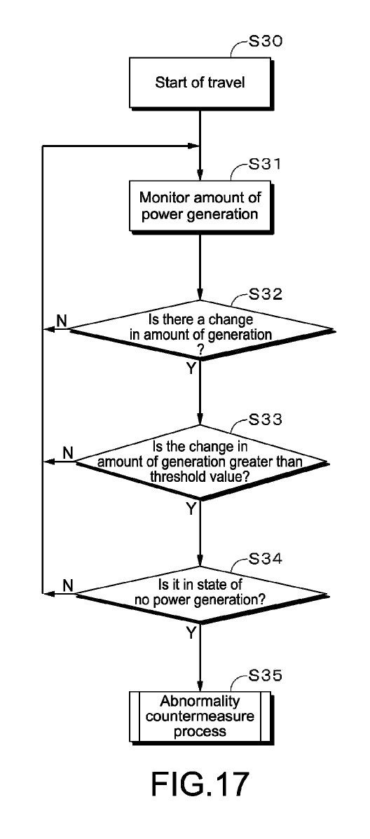

With reference to a flowchart of FIG. 17, an example of process by the vehicle apparatus 500 will be described. The vehicle C starts traveling (step S30). The vehicle C causes vibration due to its traveling. The power generation section 501 generates power in accordance with the vibration of the vehicle C. A voltage waveform which is generated due to the power generation by the power generation section 501 is fed to the control section 505. The control section 505 converts the voltage waveform into a digital signal, for example. The voltage waveform converted into the digital signal is fed to the computation section 506.

In addition, for example, positional information of the vehicle C obtained by the GPS sensor 509 is sent to the external apparatus 600, via the control section 505, the communication section and the antenna 508. For example, the positional information of the vehicle C is to be sent to the external apparatus 600 periodically (for example, at one-minute intervals).

The computation section 506 obtains the amount of power generation of the power generation section 501 on the basis of the voltage waveform and monitors the amount of power generation (step S31). In normal driving, the amount of power generation of the power generation section 501 is substantially constant.

The computation section 506 determines whether or not there is a change in the amount of power generation (step S32). If there is no change, it continues process of monitoring the amount of power generation (step S31). If there is a change in the amount of power generation, there would be determined whether or not such a change is greater than a threshold value (step S33). The threshold value is set in the following manner, for example. The amount of power generation of the power generation section 501, at the time of applying a shock at substantially the same level as that in the collision of the vehicle C against such as the wall W, is measured. A difference between the amount of power generation at that time, and the amount of power generation of the power generation section 501 during the normal driving of the vehicle C, is set as the threshold value.

If the change in the amount of power generation is not greater than the threshold value, it continues the process of monitoring the amount of power generation (step S31). For example, such as in the cases where the vehicle C has stopped at a traffic light, the amount of power generation becomes almost zero. However, for example, by setting the threshold value as described above, even when the amount of power generation turns to almost zero in a normal situation, the amount of change may be made smaller than the threshold value. Therefore, it is able to prevent being mistakenly determined as abnormal when the vehicle C has stopped at a traffic light.

If the change in the amount of power generation is greater than the threshold value, the computation section 506 determines that there has been a strong-level shock to the vehicle C. In such a case, it may be assumed that the vehicle C has collided against such as the wall W, but such a case may also be seen if a large braking force is applied to the vehicle C by being subjected to sudden braking to avoid danger. Therefore, the computation section 506 determines whether or not the power generation section 501 has become in a state of no power generation (step S34). The “state of no power generation” indicates a state in which the amount of power generation of the power generation section 501 is zero or is almost zero.

If the power generation section 501 is not in the state of no power generation and generates power, it is determined that the vehicle C has become capable of traveling again. Then, the amount of power generation of the power generation section 501 would be monitored again (step S31). If the power generation section 501 is in the state of no power generation, it is determined that the vehicle C has become unable to travel. That is, from that there has been a strong-level shock to the vehicle C, and from that the vehicle C has become unable to travel, the computation section 506 determines that the vehicle C has encountered an accident. Then, an abnormality countermeasure process by the vehicle apparatus 500 would be performed (step S35).

The abnormality countermeasure process is, for example, a process of notifying to the external apparatus 600 about having caused an accident. For example, upon determining that the vehicle C has encountered an accident, the computation section 506 notifies such fact to the control section 505. The control section 505 generates an accident occurrence signal in response to this notification. The accident occurrence signal is sent to the external apparatus 600 via the communication section 507 and the antenna 508.

The external apparatus 600 performs an abnormality countermeasure process which is configured to be performed in the external apparatus 600, in response to the accident occurrence signal. For example, on the basis of the positional information sent from the vehicle apparatus 500, it identifies the place where the vehicle apparatus 500 is located. A process to dispatch a police officer or a guard to the place where the vehicle apparatus 500 is located is performed. Other processes may be carried out as the abnormality countermeasure process as well.

For example, it may be configured such that it notifies other vehicle drivers that there is an accident occurred at the place where the vehicle apparatus 500 is located. For example, the notification to the other drivers is made by using broadcasting and navigation system. It may be configured such that there is made a call to such as a mobile phone of the user of the vehicle apparatus 500 to check the safety of the user.

### Modified Examples of Third Embodiment

The third embodiment may be modified as follows, for example. For example, in sending the accident occurrence signal from the vehicle apparatus 500 to the external apparatus 600, the positional information of the vehicle apparatus 500 obtained by the GPS sensor 509 may be made to be sent. Furthermore, it may be configured such that the sensor information obtained from other sensors such as the acceleration sensor 510 is to be sent to the external apparatus 600.

In the place of the amount of power generation of the power generation section 501, the maximum level of the power generation may be monitored. It may be configured to determine that there has been a strong shock to the vehicle C in the cases where the maximum level is greater than a predetermined level.

From the vehicle apparatus 500 to the external apparatus 600, information indicating the amount of power generation of the power generation section 501 may be made to be sent in real time or periodically. Further, it may be configured such that the external apparatus 600 determines whether or not the vehicle C has encountered an accident or the like. The external apparatus 600 may be made up as a discriminating apparatus.

### 4. Modified Examples

Although in the foregoing there have been described some embodiments of the present disclosure, the present disclosure is not limited to the above-described embodiments, but is possible to be modified in various ways. In the following, modified examples will be described.

The method to obtain the positional information is not limited to the method using the positional information to be obtained by the GPS sensor. For example, positional information of base stations for such as mobile phones, wireless LAN (Local Area Network) Hotspots and base stations for long-range wireless LAN may be set as the mobile terminal user's current location. In the case of the wireless LAN, there may be used a system of Place Engine (registered trademark) which utilizes many registered access point networks. By using their information with the positional information obtained by the GPS sensor in combination, it is able to estimate the current location of the user of such as the mobile terminal accurately.

The present disclosure is not only that it discriminates such as the presence or absence of a suspicious individual and deconditioning of a user, but

The present disclosure is not only that it discriminates the presence or absence of a suspicious individual, deconditioning of the user, and the like, but is also possible to be widely applied as apparatus for discriminating the presence or absence of other various abnormalities.

In addition to the apparatus, the present disclosure can be implemented as a method and as a system which includes a plurality of apparatus. Furthermore, the present disclosure can be applied to a so-called cloud system, in which a process of those which have been illustrated is to be distributed and processed by a plurality of apparatus. For example, in a system in which a whole or a part of the illustrated process is to be carried out, the present disclosure may also be configured as an apparatus which performs a part of process out of that whole or part of the process.

It should be noted that the configurations and the processes in the embodiments and the modified examples are each merely an example, allowing a configuration and the like to be added, removed or modified, as appropriate, insofar as no technical contradiction arises therefrom. Furthermore, configurations, materials, communication methods and the like, which have been illustrated in the embodiments and the modified examples can be combined, as appropriate, insofar as no technical contradiction arises therefrom.

The present technology may take the following configurations.

(1) A discriminating apparatus, including:

a discrimination section configured to discriminate the presence or absence of an abnormality, in accordance with information on power generation from a power generation section.

(2) The discriminating apparatus according to (1), in which

the power generation section is formed by being disposed a plurality of power generation elements at a contact member.

(3) The discriminating apparatus according to (2), in which

by moving of a moving object to a predetermined area on the contact member, the power generation element corresponding to the predetermined area generates power.

(4) The discriminating apparatus according to (3), in which

the information on power generation includes positional information of the power generation element having generated power, and

the discrimination section is configured to discriminate the presence or absence of an abnormality in accordance with the positional information.

(5) The discriminating apparatus according to (3), in which

the information on power generation includes an amount of power generation of the power generation element having generated power, and

the discrimination section is configured to discriminate the presence or absence of an abnormality in accordance with the amount of power generation of the power generation element having generated power.

(6) The discriminating apparatus according to any one of (2) to (5), in which

the plurality of power generation elements is disposed in matrix form at the contact member.

(7) The discriminating apparatus according to any one of (2) to (6), in which

the power generation element generates power by a pressure applied due to the movement of a moving object.

(8) The discriminating apparatus according to (1), in which

the discrimination section is configured to discriminate the presence or absence of an abnormality in accordance with the information on power generation and sensor information from a sensor section.

(9) The discriminating apparatus according to (8), in which

the sensor information includes information indicating at least one of a user's location, direction of movement of the user and a body situation of the user.

(10) The discriminating apparatus according to (1), in which

the information on power generation includes information indicating a change in an amount of power generation, and

the discrimination section discriminates that there is the abnormality, in a case where the change in the amount of the power generation is greater than a threshold value.

(11) The discriminating apparatus according to (10), further including:

a positional information-obtaining section configured to obtain positional information of a moving object, and

a sending section configured to send the positional information to other apparatus at least in the case where the abnormality is discriminated to be present.

(12) The discriminating apparatus according to any one of (1) to (11), in which

power is supplied from the power generation section to the discrimination section.

(13) The discriminating apparatus according to any one of (1) to (12), further including:

a processing section configured to perform a process to address the abnormality in the case where the abnormality is discriminated to be present.

(14) The discriminating apparatus according to any one of (1) to (13), in which

the power generation section generates power on the basis of the energy present in the surrounding environment.

(15) A discriminating method in a discriminating apparatus, including:

discriminating the presence or absence of an abnormality in accordance with information on power generation from a power generation section.

(16) A discriminating system, including:

a power generation section which generates power on the basis of the energy present in the surrounding environment; and

a discrimination section configured to discriminate the presence or absence of an abnormality, in accordance with information on power generation from the power generation section.

The present disclosure contains subject matter related to that disclosed in Japanese Priority Patent Application JP 2012-051556 filed in the Japan Patent Office on Mar. 8, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A discriminating apparatus, comprising:
a discrimination section configured to discriminate the presence or absence of an abnormality, in accordance with information on power generation from a power generation section.

2. The discriminating apparatus according to claim 1, wherein
the power generation section is formed by being disposed a plurality of power generation elements at a contact member.

3. The discriminating apparatus according to claim 2, wherein
by moving of a moving object to a predetermined area on the contact member, the power generation element corresponding to the predetermined area generates power.

4. The discriminating apparatus according to claim 3, wherein
the information on power generation includes positional information of the power generation element having generated power, and
the discrimination section is configured to discriminate the presence or absence of an abnormality in accordance with the positional information.

5. The discriminating apparatus according to claim 3, wherein
the information on power generation includes an amount of power generation of the power generation element having generated power, and
the discrimination section is configured to discriminate the presence or absence of an abnormality in accordance with the amount of power generation of the power generation element having generated power.

6. The discriminating apparatus according to claim 2, wherein
the plurality of power generation elements is disposed in matrix form at the contact member.

7. The discriminating apparatus according to claim 2, wherein
the power generation element generates power by a pressure applied due to the movement of a moving object.

8. The discriminating apparatus according to claim 1, wherein
the discrimination section is configured to discriminate the presence or absence of an abnormality in accordance with the information on power generation and sensor information from a sensor section.

9. The discriminating apparatus according to claim 8, wherein
the sensor information includes information indicating at least one of a user's location, direction of movement of the user and a body situation of the user.

10. The discriminating apparatus according to claim 1, wherein
the information on power generation includes information indicating a change in an amount of power generation, and
the discrimination section discriminates that there is the abnormality, in a case where the change in the amount of the power generation is greater than a threshold value.

11. The discriminating apparatus according to claim 10, further comprising:
a positional information-obtaining section configured to obtain positional information of a moving object, and
a sending section configured to send the positional information to other apparatus at least in the case where the abnormality is discriminated to be present.

12. The discriminating apparatus according to claim 1, wherein
power is supplied from the power generation section to the discrimination section.

13. The discriminating apparatus according to claim 1, further comprising:
a processing section configured to perform a process to address the abnormality in the case where the abnormality is discriminated to be present.

14. The discriminating apparatus according to claim 1, wherein
the power generation section generates power on the basis of the energy present in the surrounding environment.

15. A discriminating method in a discriminating apparatus, comprising:
discriminating the presence or absence of an abnormality in accordance with information on power generation from a power generation section.

16. A discriminating system, comprising:
a power generation section which generates power on the basis of the energy present in the surrounding environment; and
a discrimination section configured to discriminate the presence or absence of an abnormality, in accordance with information on power generation from the power generation section.
